(19) United States
(12) Patent Application Publication
(10) Pub. No.: US 2023/0116857 A1
(43) Pub. Date: Apr. 13, 2023

(54) ADVANCED HYBRID 3D STACKING FOR 3D ARCHITECTURAL DESIGN AND LAYOUT

(71) Applicant: Tokyo Electron Limited, Tokyo (JP)

(72) Inventors: Mark I. Gardner, Albany, NY (US); H. Jim Fulford, Albany, NY (US)

(73) Assignee: Tokyo Electron Limited, Tokyo (JP)

(21) Appl. No.: 17/881,536

(22) Filed: Aug. 4, 2022

Related U.S. Application Data
(60) Provisional application No. 63/253,946, filed on Oct. 8, 2021.

(51) Int. Cl. H01L 29/06; H01L 27/06; H01L 29/417; H01L 29/786; H01L 21/8238

(52) U.S. Cl. CPC H01L 29/0673; H01L 27/0688; H01L 29/41733; H01L 29/78696; H01L 21/823807; H01L 21/823814

(57) ABSTRACT

The solution provides structures and fabrication steps for manufacturing a device that includes a core comprising a dielectric material extending vertically from a substrate and a vertical shell having a cross-section having a rounded portion. The vertical shell can include an epitaxially grown semiconductor material that at least partially surrounds the core and forms a channel of a transistor. The core can include a second vertical shell including a second epitaxially grown semiconductor material that at least partially surrounds the core and forms a second channel of the transistor.

### CROSS-REFERENCE TO RELATED APPLICATIONS

This application claims priority to U.S. Provisional Application Ser. No. 63/253,946, filed Oct. 8, 2021, which is incorporated by reference in its entirety.

### TECHNICAL FIELD

This disclosure related to microelectronic devices including semiconductor 3D devices and design as well as methods of fabrication.

### BACKGROUND

Fabrication of semiconductor devices relies on execution of various fabrication processes that are performed repeatedly in order to form desired semiconductor features on a substrate. In the recent years, scaling down semiconductor devices became more challenging as features sizes reached single digit nanometer range.

### SUMMARY

In order to continue scaling down semiconductor devices, device structures can be designed to extend in their vertical direction, such as upwards from the substrate on which they are fabricated. The present disclosure provides three-dimensional (3D) semiconductor circuits in which transistors can be designed to extend in vertical direction, as well as be stacked on top of each other, thereby allowing for greater number of devices to be fabricated within a substrate surface area. The present solution can also provide improved electrical properties of semiconductor structures fabricated in the 3D vertical orientation, utilizing 3D channels and vertically oriented nanosheet devices. The present solution can provide epitaxially grown nanosheets which can be co-integrated with different epitaxially grown semiconductors for CMOS and other device elements, as well as techniques and methodologies for their fabrication. The present solution can also provide for vertically segmented nanosheet devices with 3D channels formed around vertically oriented support structures and 3D electrical isolation approach allowing for dense arrays of such devices.

In some aspects, the present disclosure relates to a device. The device can include a semiconductor transistor device, such as a vertical FET device having a core structure about which vertically oriented channels are formed from epitaxially grown doped semiconductor materials. The device can include a core comprising a dielectric material extending vertically from a substrate. The device can include a vertical shell having a cross-section comprising a rounded portion, the vertical shell comprising an epitaxially grown semiconductor material that at least partially surrounds the core and forms a channel of a transistor.

The device can include the vertical shell that is isolated from the substrate by a dielectric layer. The device can include a bottom portion of a dielectric vertical shell isolating the substrate from the vertical shell that is formed thereon, wherein the dielectric vertical shell has a cross-section comprising the rounded portion and at least partially surrounds the core. The device can include a first source/drain contact on an outer surface of the shell and a second source/drain contact on the outer surface of the shell. The second source/drain contact can be vertically aligned with the first source/drain contact. The second source/drain contact can include the same electrically conductive material as the first source drain contact.

The device can include a gate contact on an outer surface of the shell. The gate contact can be located between, and vertically aligned with, the first source/drain contact and the second source/drain contact. The device can include a first source/drain contact extending along an outer surface of the cross-section of the vertical shell and a second source/drain contact extending along an outer surface of the second cross-section of the vertical shell.

The device of claim 1, wherein the rounded portion of the cross-section comprises an outer surface of the vertical shell and wherein the cross-section further comprises a second rounded portion of the cross-section along an inner surface of the outer shell. The device can include a cross-section of the core comprising a portion that is one of: circular, elliptical or polygonal. The cross-section of the vertical shell comprises a portion that is one of: circular, elliptical or polygonal.

The device can include the vertical shell that extends across a first portion of the outer surface of the core. The device can include a second vertical shell having a rounded cross-section and comprising an epitaxially grown second semiconductor material that at least partially surrounds the dielectric core. The second vertical shell can form a second channel of a second transistor. The second vertical shell can extend across a second portion of the outer surface of the core.

The device can include the semiconductor material of the vertical shell that is different from the second semiconductor material of the second vertical shell. The semiconductor material of the vertical shell can be electrically insulated from the second semiconductor material of the second vertical shell by one or more layers of dielectric. The device can include the semiconductor material that includes a first material dopant type and the second semiconductor that includes a second material dopant type that is different from than the first material dopant type.

In some aspects the present disclosure relates to a method. The method can be a method for fabricating semiconductor transistor device, such as a vertical FET device having a core structure about which vertically oriented channels are formed from epitaxially grown doped semiconductor materials. The method can include forming a core comprising a dielectric material extending vertically from a substrate and having a rounded shape. The method can include forming a vertical shell having a surface that contacts the core and includes a rounded portion defined by the rounded shape of the core. The vertical shell can include an epitaxially grown semiconductor material that at least partially surrounds the core and forms a channel of a transistor.

The method can include vertical shell that is provided on a substrate. The method can include isolating the vertical shell from the substrate by a dielectric layer. The method can include forming a dielectric vertical shell that contacts and at least partially surrounds the core and includes a rounded portion defined by the rounded shape of the core. Dielectric vertical shell can have the cross-section comprising the rounded portion and at least partially surrounding the core. The method can include removing a top portion of the dielectric vertical shell. The method can include forming the vertical shell on top of a bottom portion of the dielectric vertical shell, wherein the bottom portion isolates the vertical shell from the substrate. The method can include forming a first source/drain contact on an outer surface of the shell. The method can include forming a second source/drain contact on the outer surface of the shell. The method can include vertically aligning the second source/drain contact with the first source/drain contact.

The method can include forming a gate contact on an outer surface of the shell. The gate contact can be located between, and vertically aligned with, the first source/drain contact and the second source/drain contact. The method can include forming a first source/drain contact extending along a surface of the vertical shell opposite the core and a second source/drain contact extending along an outer surface of the vertical shell opposite the core.

The method can include replacing a preliminary core with the core comprising the dielectric material. . The method can include forming a cross-section of the core comprising a portion that is one of: circular, elliptical or polygonal. The method can include a surface of the vertical shell that is defined by the cross-section.

The method can include the vertical shell that extends across a first portion of the outer surface of the core. The method can include forming a second vertical shell. The second vertical shell can include surface defined by the cross-section. The second vertical shell can include an epitaxially grown second semiconductor material that at least partially surrounds the core. The method can form a second channel of a second transistor, wherein the second vertical shell extends across a second portion of the outer surface of the core.

The method can include the semiconductor material of the vertical shell that is different from the second semiconductor material of the second vertical shell. The semiconductor material of the vertical shell can be is electrically insulated from the second semiconductor material of the second vertical shell by one or more layers of dielectric.

The method can include forming the semiconductor material of the vertical shell that comprises a first material dopant type and the second semiconductor material of the second vertical shell that includes a second material dopant type that is different from than the first material dopant type.

These and other aspects and implementations are described in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects can be combined and it will be readily appreciated that features described in the context of one aspect of the present disclosure can be combined with other aspects. Aspects can be implemented in any convenient form. As used in the specification and in the claims, the singular form of ‘a’, ‘an’, and ‘the’ include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 is a cross-sectional and a top-down illustration of an example structure in which a single shell is formed around the sidewalls of each of the core structures formed on a substrate, in accordance with an embodiment.

FIG. 2 is a cross-sectional and a top-down illustration of an example structure in which multiple shells are formed around the sidewalls of each of the core structures formed on a substrate, in accordance with an embodiment.

FIGS. 3-11 are cross-sectional and top-down illustrations of an example fabrication flow steps for manufacturing a structure having a vertical core surrounded by single ring shell, in accordance with another embodiment.

FIGS. 12-20 are cross-sectional and top-down illustrations of an example fabrication flow steps for manufacturing a structure having a vertical core surrounded by single ring shell, in accordance with another embodiment.

FIG. 21-29 are cross-sectional and top-down illustrations of an example fabrication flow steps for manufacturing a structure having a vertical core surrounded by single ring shell, in accordance with another embodiment.

FIG. 30 is a series of top-down illustrations, showing a flow diagram of an example method for fabricating a structure having a vertical core surrounded by single ring shell, in accordance with another embodiment.

FIG. 31 is a series of top-down illustrations, showing a flow diagram of an example method for fabricating a structure having a vertical core surrounded by single ring shell, in accordance with another embodiment.

FIG. 32-42 are cross-sectional and top-down illustrations of an example fabrication flow steps for manufacturing a structure having a vertical core surrounded by multiple ring shells forming channels for semiconductor transistors, in accordance with an embodiment.

FIG. 43-59 are cross-sectional and top-down illustrations of an example fabrication flow steps for manufacturing a structure having a vertical core surrounded by multiple ring shells forming channels for semiconductor transistors, in accordance with another embodiment.

FIGS. 60-75 are cross-sectional and top-down illustrations of an example fabrication flow steps for manufacturing a structure having a vertical core surrounded by multiple ring shells forming channels for semiconductor transistors, in accordance with an embodiment.

FIG. 76 is a flow diagram of an example method for fabricating transistor structures, including Si-based and Ge-based structures with silicide and germanicide regions, in connection with FIGS. 1-75, according to one or more embodiments.

### DETAILED DESCRIPTION

Reference will now be made to various illustrative embodiments depicted in the drawings, and specific language will be used to describe the same. It will nevertheless be understood that no limitation of the scope of the claims or this disclosure is thereby intended. Alterations and further modifications of the inventive features illustrated herein, and additional applications of the principles of the subject matter illustrated herein, which would be apparent to one of ordinary skill in the relevant art having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

It is understood that apparatuses, systems and devices produced by the structures described herein can be used or find their application in any number of electronic devices utilizing structures and/or circuits described herein, such as for example, controllers, memory chips, systems or process on a chip processors, graphics processing units, central processing units and more. For example, structures and/or circuits described herein can include a part of systems including or utilizing memory, such as any computing systems including for example: computers, phones, servers, cloud computing devices, and any other device or system that utilizes integrated circuit devices.

The embodiments described herein may enable an increased stack height of one or more 3D semiconductor devices. Therefore, a semiconductor substrate can be used, but is not required, and any base layer material (e.g., glass, organic, etc.) may be used instead of a silicon substrate. A base layer, therefore, can be a semiconductor substrate, such as a silicon substrate or any other semiconductor, ceramic, metal or other material substrate.

The process flows described herein can utilize conductive dielectric materials to form NMOS and PMOS devices. As such, the techniques described herein can be used to produce devices that are manufactured, or “stacked” on any existing vertically stacked device or substrate, according to various implementations. The present techniques may improve upon other semiconductor manufacturing techniques by increasing the N height of stacked semiconductor devices, such as transistors, thereby providing high density logic. Although illustrations herein may show an NMOS device arranged over a PMOS device, alternative configurations may include a PMOS device over NMOS device, NMOS device over NMOS device, PMOS device over PMOS device, or other alternative including one or more NMOS devices or PMOS devices for any number of N stacks and in any order or arrangement.

Dielectric materials used herein can be any material or materials having low electrical conductivity, such as for example one millionth of a mho/cm. Dielectric materials can include, for example, silicon dioxide, silicon nitride, nanoporous silica, hydrogensilsesquioxanes (HSQ), Teflon-AF (Polytetrafuoethene or PTFE), Silicon Oxyflouride. Dielectric materials can also include, for example, ceramics, glass, mica, organic and oxides of various metals.

A high-k dielectric, also referred to as high-k material, can refer to any material with a higher dielectric constant as compared to the silicon dioxide. For example, high-k dielectric can include hafnium silicate, zirconium silicate, hafnium dioxide, zirconium dioxide, and others.

Various metals, such as gate metal and the source/drain metal, can be used herein and can include any metal or any electrically conductive material. For example, metals used in the present solution can include aluminum, copper, titanium, ruthenium, titanium, tungsten, silver, gold or any other metal. For the purposes of the present solution, in addition to the metals, source/drain metals or gate metals can also include other electrically conductive materials, such as highly doped semiconductors, for example.

The present solution can also utilize 2D materials for forming transistor channels. 2D materials can include, for example, but are not limited to, WS2, WSe2, WTe2, MoS2, MoSe2, MoTe2, HfS2, ZrS2, and TiS2, GaSe, InSe, phosphorene, and other similar materials. These materials can be deposited by an atomic layer deposition (ALD) process and may be about 5-15 angstroms thick, the thinness lending to their name—2D material. 2D material layer can, depending on the material and design, and can have a broader range of thicknesses, such as between 0.2 nm and 3 nm, for example. 2D materials may be annealed during or after the device formation process to recrystallize or grow the crystals and thereby improve electrical characteristics. 2D materials, for example, can be electrically conductive.

Additionally or alternatively, 2D materials to be used for forming 2D channels may comprise one or more semiconductive-behaving materials, which may be formed using certain elements that, when combined with oxygen, form a new material that exhibits semiconductive behavior. For example, the semiconductive behaving material can be “turned off” and can have a low or practically no off-state leakage current, and can be “turned on” and become highly conductive when voltage is applied. Example materials to create an n-type channel for example include, but are not limited to, In2O3, SnO2, In GaZnO, and ZnO. Example materials that can be used to create a p-type channel may be formed utilizing, for example, SnO. These materials may be further doped to improve the electrical characteristics. These materials may also be referred to as conductive oxides or semiconductive behaving oxides for the purposes of this discussion.

As 2D materials can have a very large mobility, they can be herein described as one embodiment, however it is to be appreciated that other non-epitaxially grown materials can be utilized. Since a 2D material can be precisely deposited on an insulative sheet, this can enable a very low Dt integration build of horizontal nanosheets with high performance. Advantageously, any base substrate material can be utilized as no epitaxial growth is required and the base substrate can be removed for further stacking of the devices.

Carrier nanosheets can be used to provide support for the 2D material layers. Carrier nanosheets can include dielectric materials or semiconductor materials on which 2D material layer, such as a monolayer of 2D material, can be deposited, grown or otherwise formed. Carrier nanosheet can include an electrically insulating material that can be used as a seed layer for the 2D material(s) used in the stack. Additionally or alternatively, a seed layer can include a material that can be deposited onto a carrier nanosheet, onto which a layer of 2D material can be formed, deposited or applied.

The present disclosure can also refer to conductive oxide materials. Conductive oxides can include certain types of materials that include elements combined with oxygen to form a new material that exhibits semiconductor properties, including being able to turn off with low off state leakage current under some conditions and be highly conductive under other conditions. For example, N type conductive channels can be formed with In₂O₃, SnO₂, InGaZnO and ZnO. P type conductive channels can be formed with SnO. Using these materials, N-type and P-type transistors can be formed using conductive oxides. In some instances, conductive oxides can be used instead of or together with 2D materials, and vice versa.

The order of description or fabrication steps performed or described herein has been presented for clarity sake and as an example. The fabrication steps described herein can be performed in any suitable order. Additionally, although each of the different features, techniques, configurations described herein may be described in different places of this disclosure, it is intended that each of the concepts can be executed independently of each other or in combination with each other. Accordingly, the solutions described herein can be embodied and viewed in many different ways.

Reference will now be made to the Figures, which for the convenience of visualizing the 3D semiconductor fabrication techniques described herein, illustrate a substrate undergoing a process flow in both top and cross-sectional views. Unless expressly indicated otherwise, each Figure represents one (or a set) of fabrication steps in a process flow for manufacturing the devices described herein. In the top and cross-sectional views of the Figures, connections between conductive layers or materials may be shown. However, it should be understood that these connections between various layers and masks are merely illustrative, and are intended to show a capability for providing such connections, and they should not be considered limiting to the scope of the claims. Conversely, when example illustrations do not show electrical connections to components that are electrically contacted, it is understood that such electrical connections can be made as understood by a person of ordinary skill.

Although the Figures and aspects of the disclosure may show or describe devices herein as having a particular shape, it should be understood that such shapes, whether of the structures or features, are used as examples of the present solution and are merely illustrative and should not be considered limiting to the scope of the techniques described herein. For example, although most of the Figures show various layers in a rectangular shaped configuration, other shapes are also contemplated, and indeed the techniques described herein may be implemented in any shape or geometry. In addition, examples in which two transistors or devices are shown stacked on top of one another are shown for illustrative purposes only, and for the purposes of simplicity. Indeed, the techniques described herein may provide for one to any number N stacked devices. Further, although the devices fabricated using these techniques are shown as transistors, it should be understood that any type of electronic device may be manufactured using such techniques, including but not limited to transistors, variable resistors, resistors, capacitors, memory components, logic gates and components and any other components known or used in the art.

Despite the fact that illustrated embodiments for simplicity and brevity show examples of only a single or double transistor structures being formed using the techniques of the present solution, any number of transistors can be formed above and beside the transistor structures illustrated in examples illustrated, such as may be desired for forming a 3D array of devices.

Techniques described herein can provide structures that can be manufactured using methods discussed herein for fabricating 3D microelectronic devices, which can include stand-alone devices or vertical transistors, including 3D sequential circuit builds. Techniques described herein can enable ultra-dense 3D design with method of integration of high performance VFETs. For instance, the present solution can include a fabrication method in which a metal gate electrode of a transistor is formed early in the process as a support or a pillar to hold or carry multiple adjacent materials that can be applied thereon while forming the transistor. In some implementations, as few as only three lithographic masks can be utilized to create an entire array of VFET structures using the gate electrode support structure to provide various instances of self-aligned directional etching.

Embodiments herein relate to the epitaxial growth of semiconductor materials in horizontal and vertical dimensions. This enables higher density circuits to be produced at reduced cost. By using a combination of Vertical and Horizontal EPI growth, optimum 3D vertical nanosheets with high mobility regions for NMOS and PMOS are achieved. Certain embodiments disclose transistors with a vertical channel that is configured around a portion of a cylinder (e.g., ½ cylinder). A second channel may also be configured around the cylinder. The channels may be coupled as part of a common transistor or other device or the channels may be isolated to form separate devices. The channels may comprise the same material or may comprise different materials. One invention example shows a 3D device in which a first channel is formed around ½ of a cylinder with Germanium (Ge), while another channel is formed around the other ½ cylinder with Silicon (Si).

The present solution can provide devices in which, for example, cylindrical post extending vertically can include an outer curved surface on which one or more nanosheets can be formed. A nanosheets can form a ring around the post, covering the entire outer surface of the post around a cross-section. In some embodiments, multiple nanosheets can be formed on the outer surface of the post, each one covering a portion of the outer surface. For example, when two nanosheets are used, the cylindrical post can include a first nanosheet covering a portion of the cylinder, while the second nanosheet can cover the remaining portion of the outer surface of the post, forming the remainder of the cylinder. Each nanosheet can form its own individual channel for a transistor device. Therefore, a single post can carry one or more transistor devices, depending on the number of nanosheet-formed channels it includes.

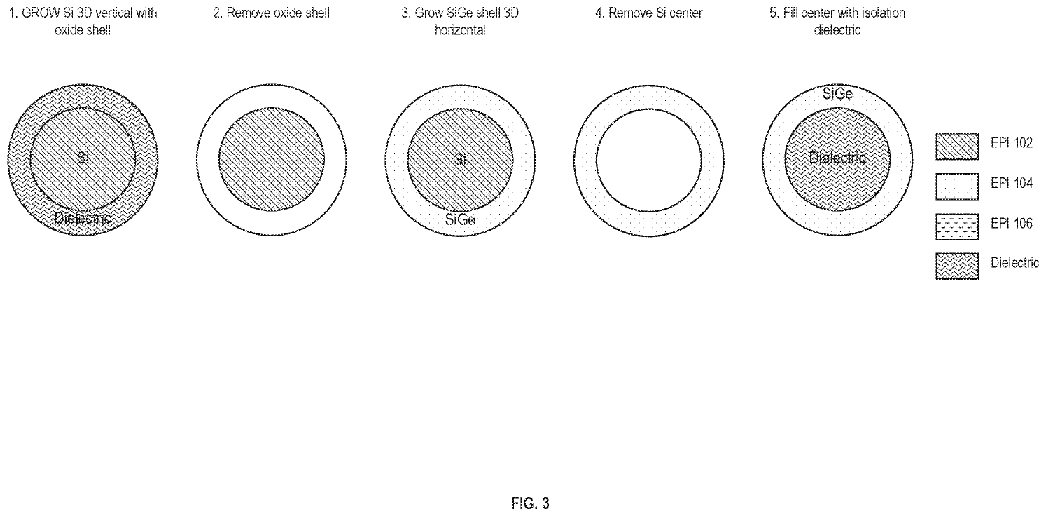

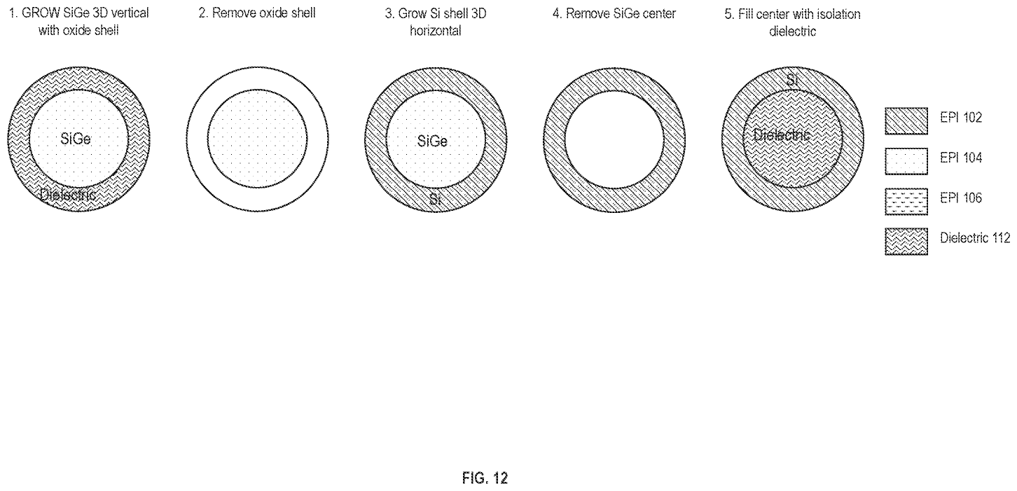

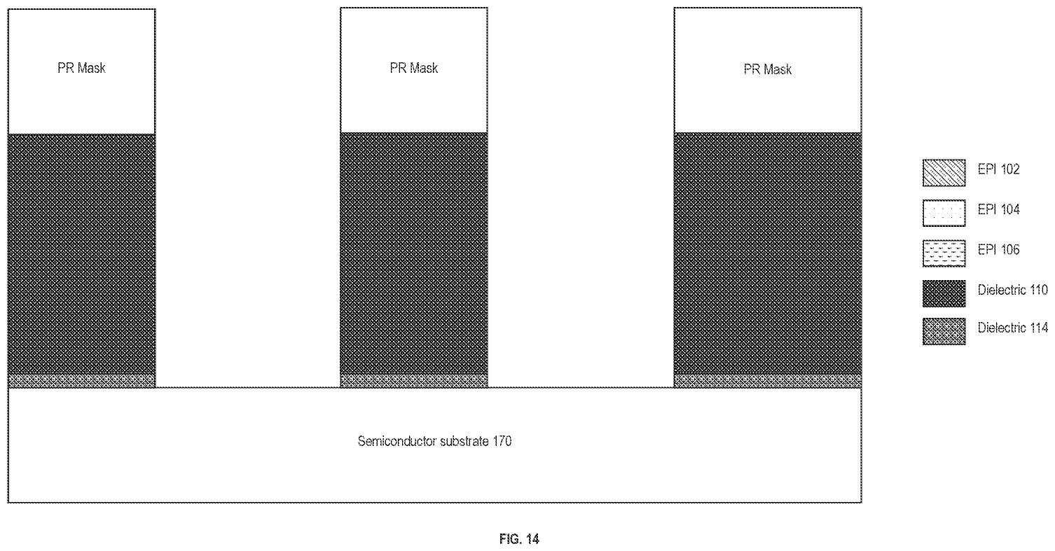

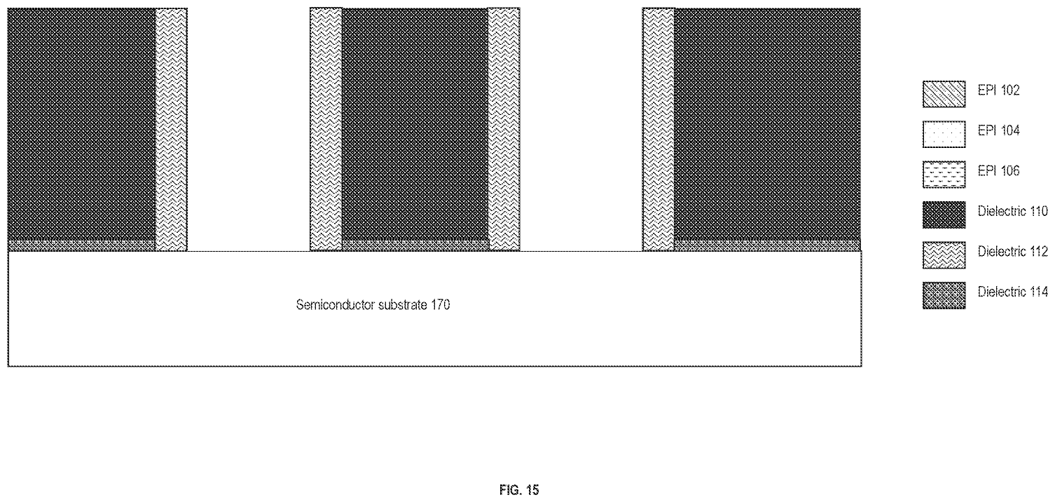

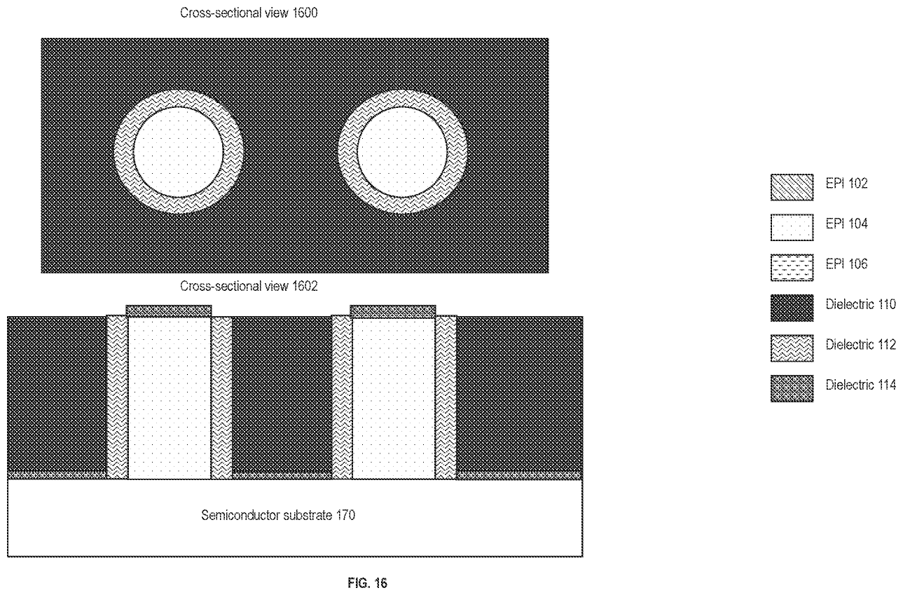

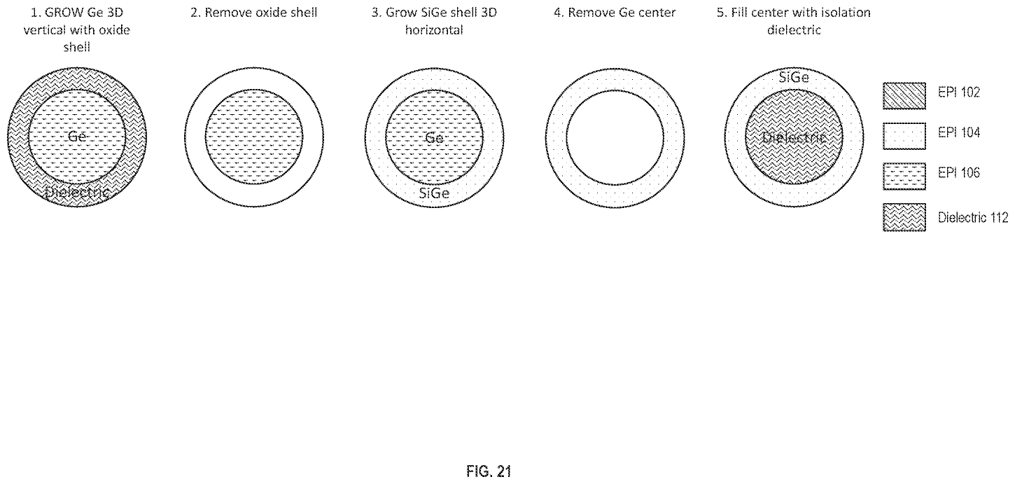

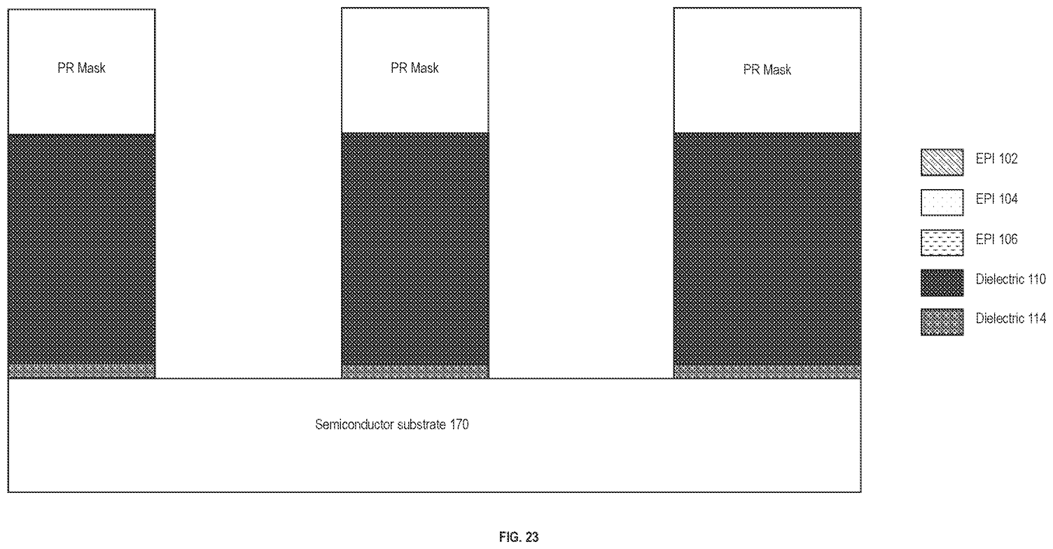

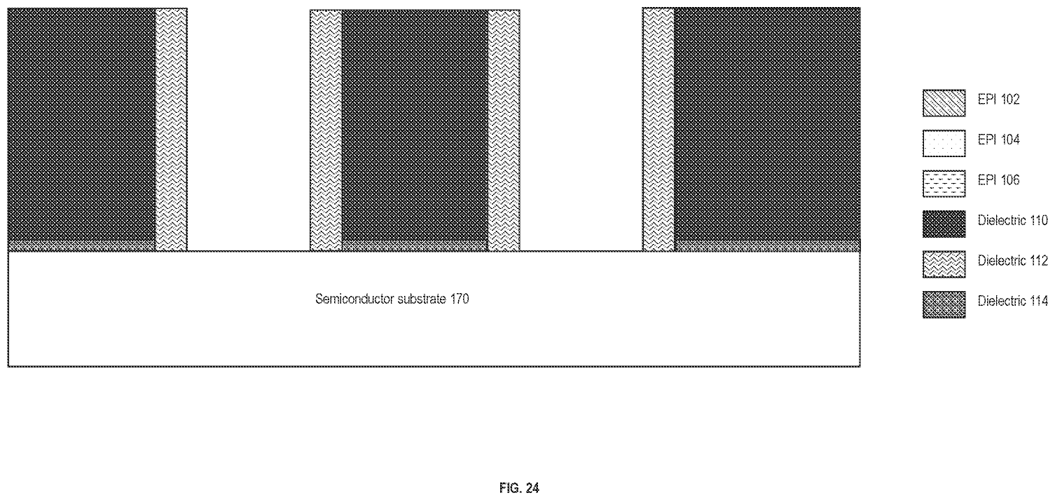

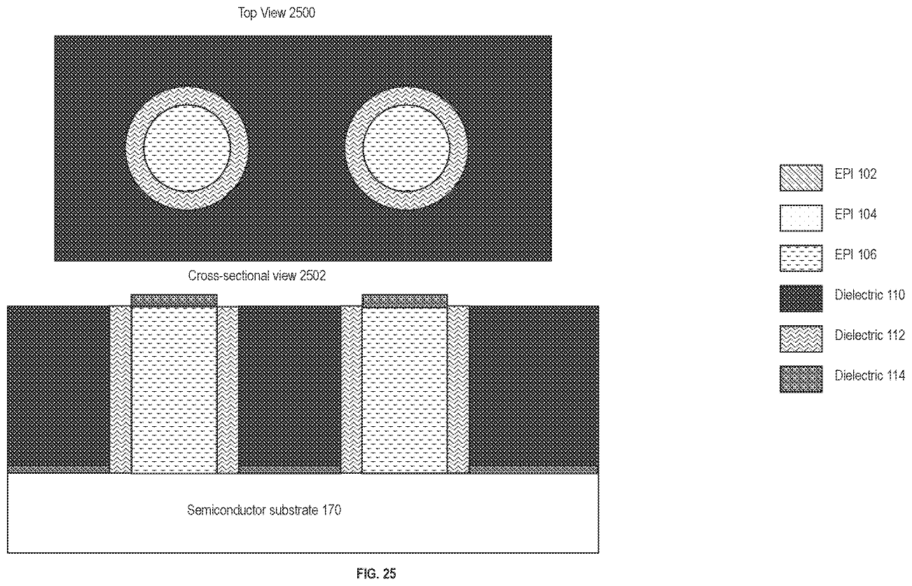

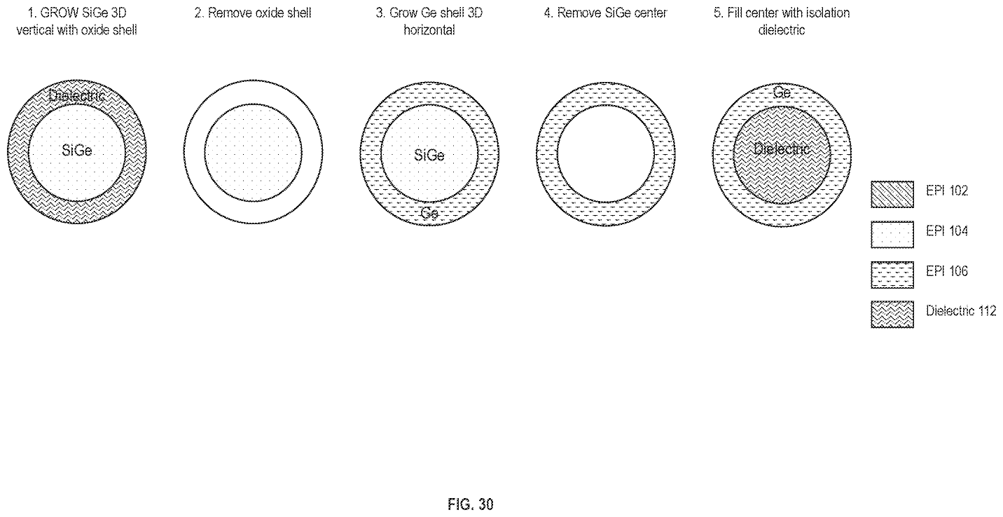

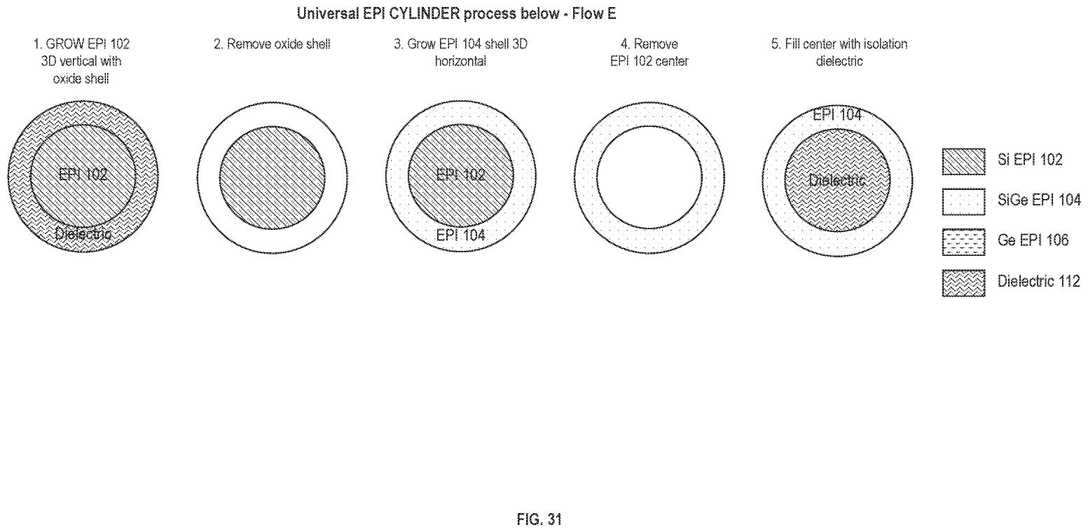

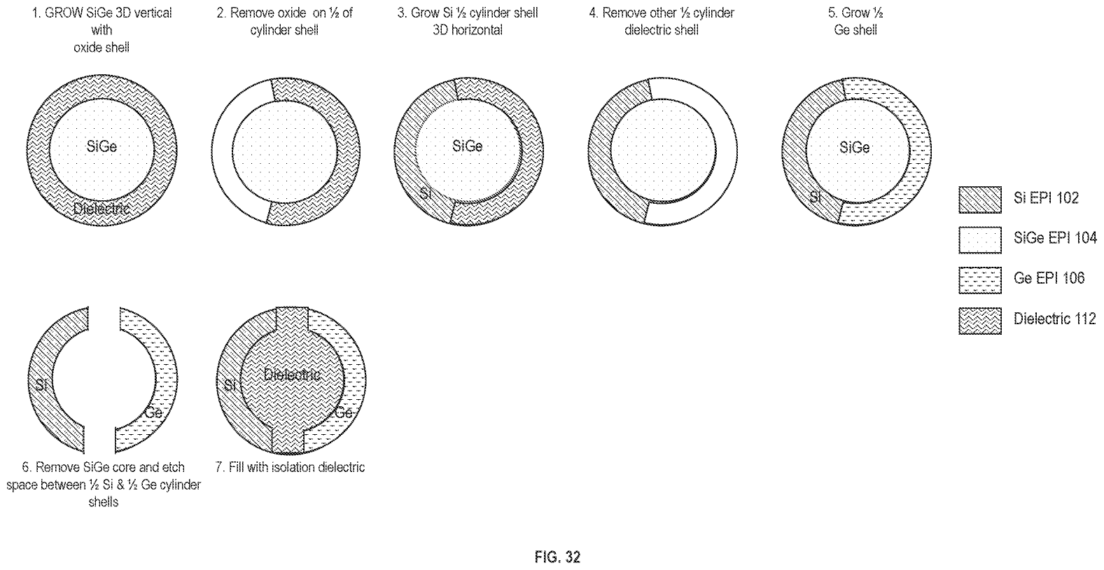

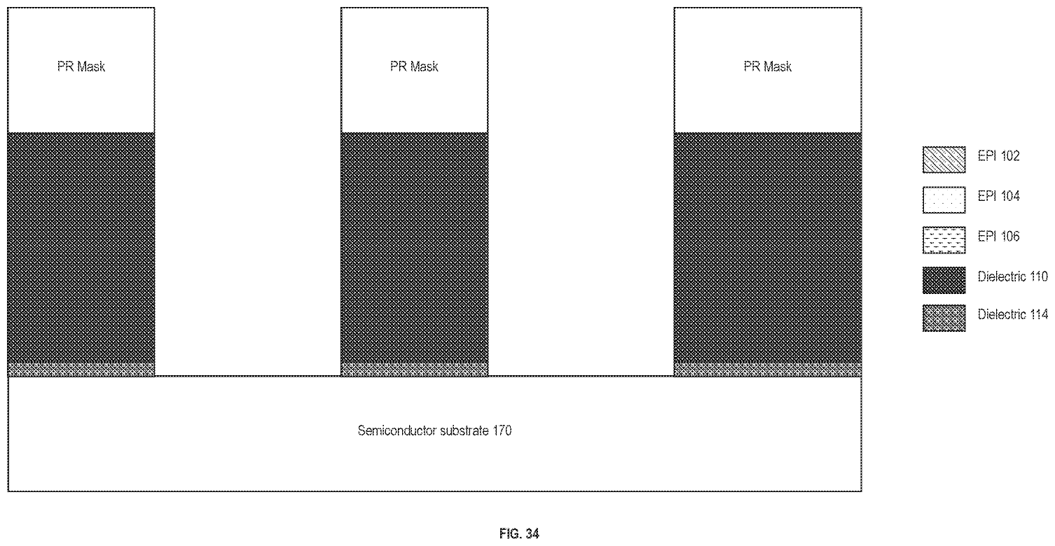

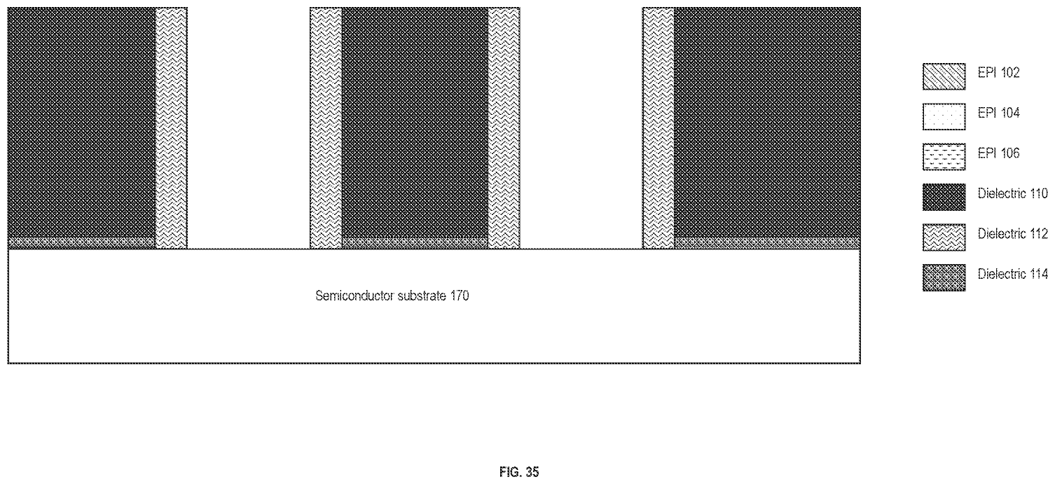

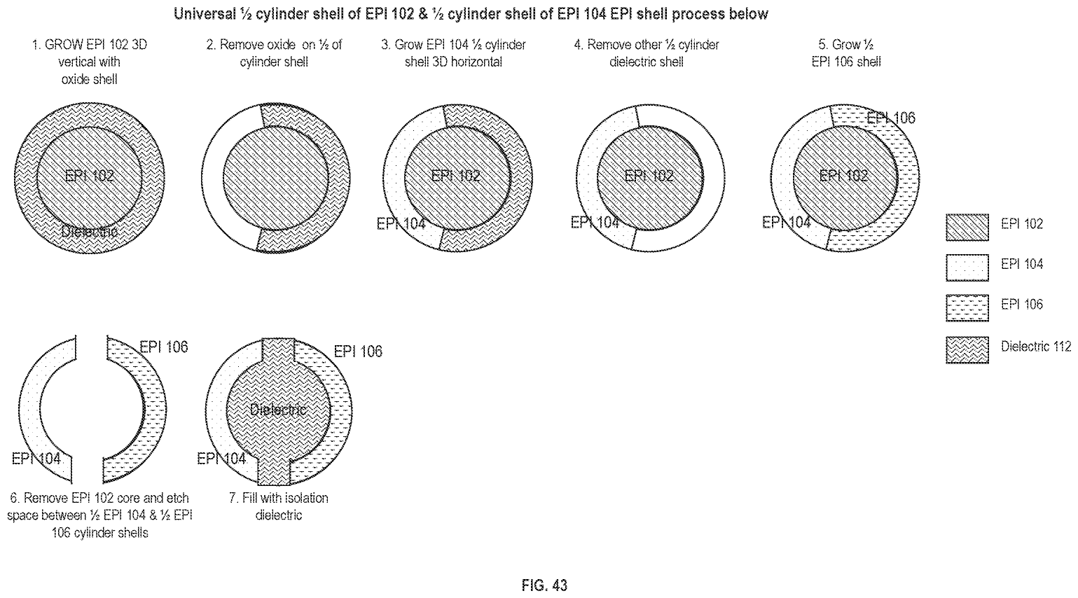

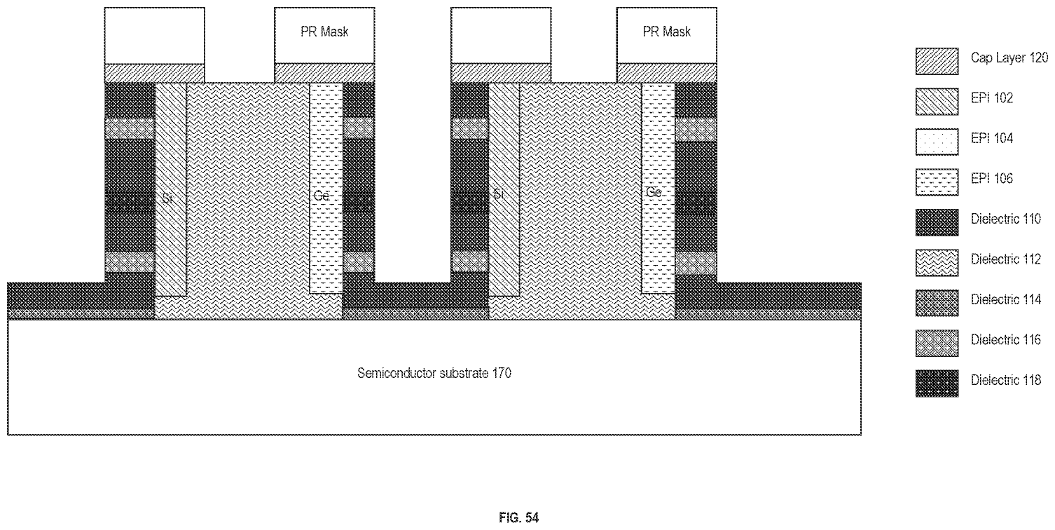

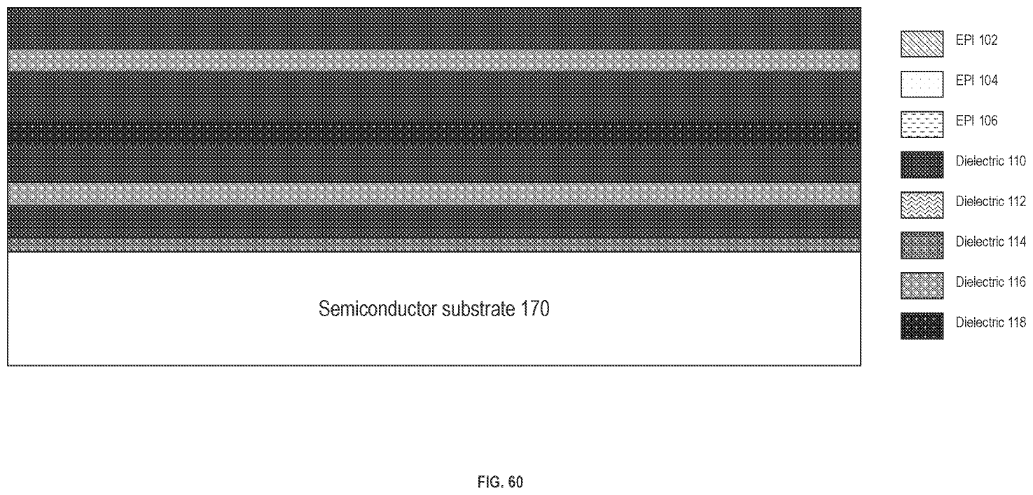

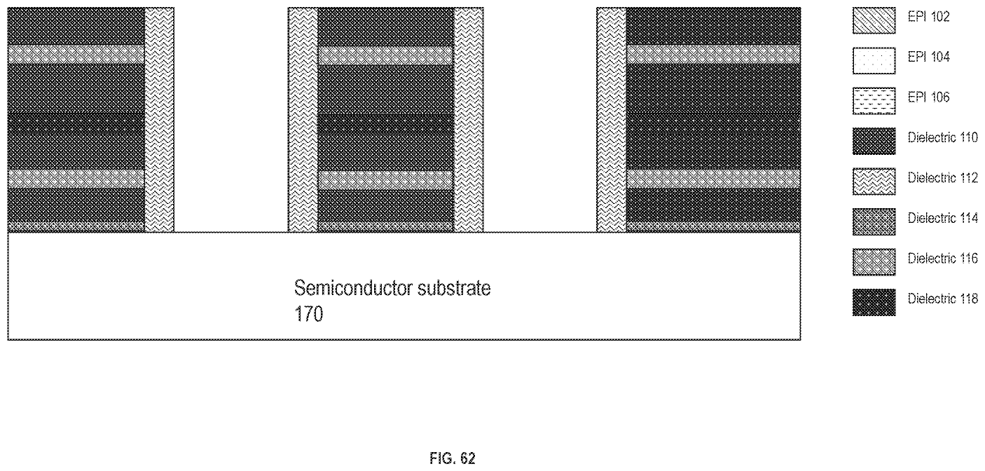

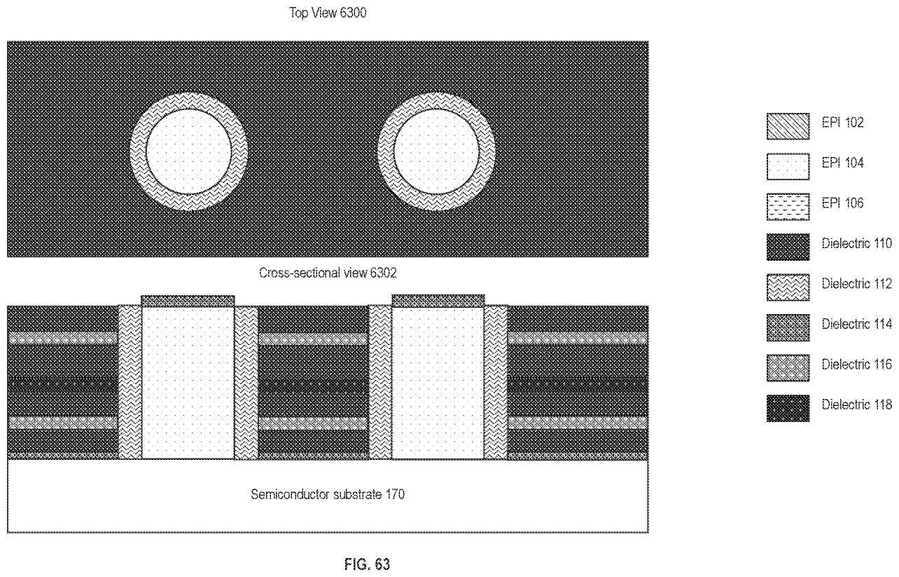

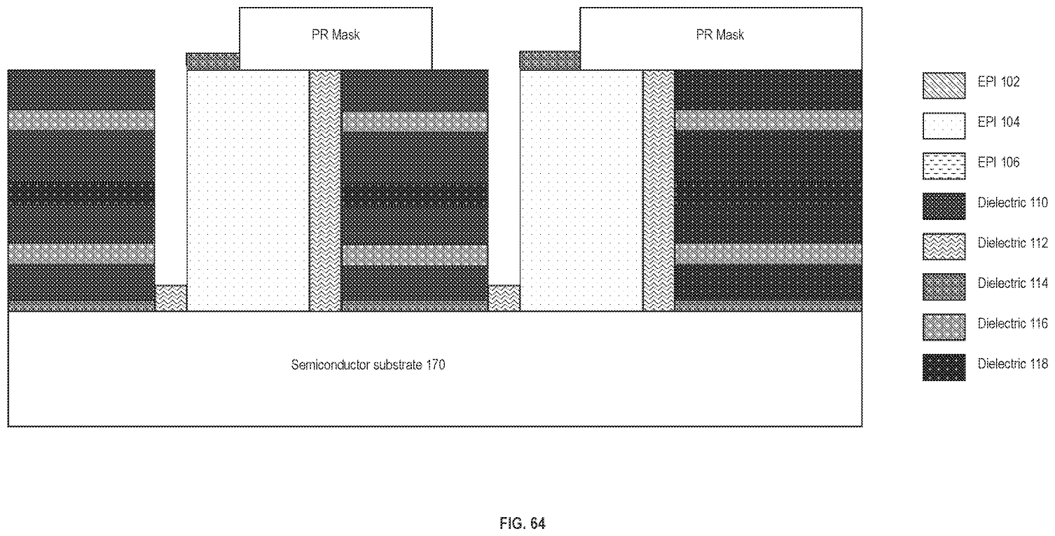

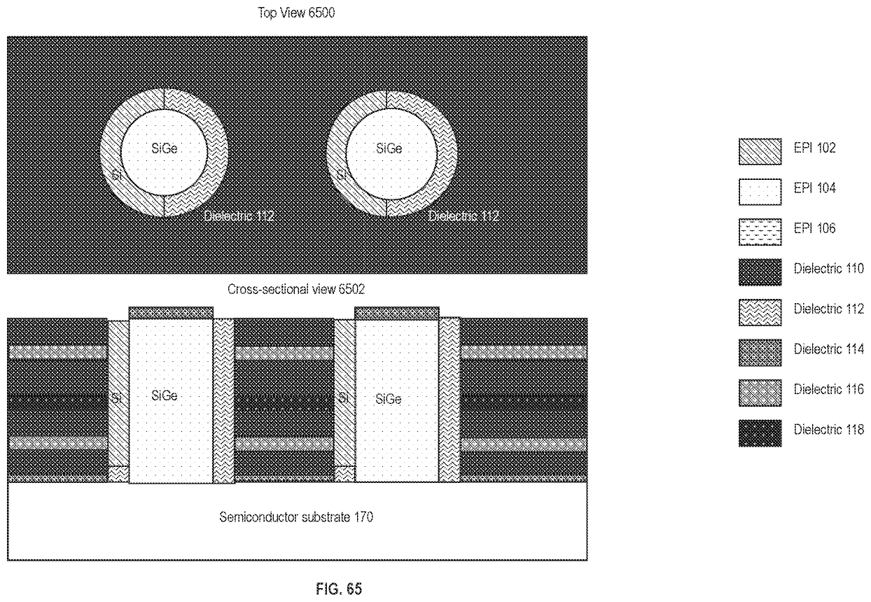

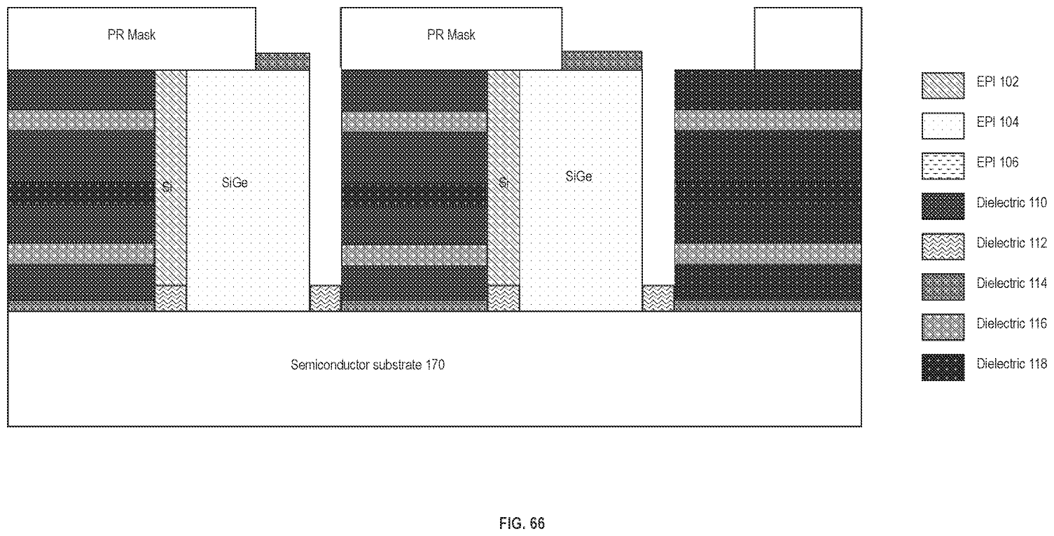

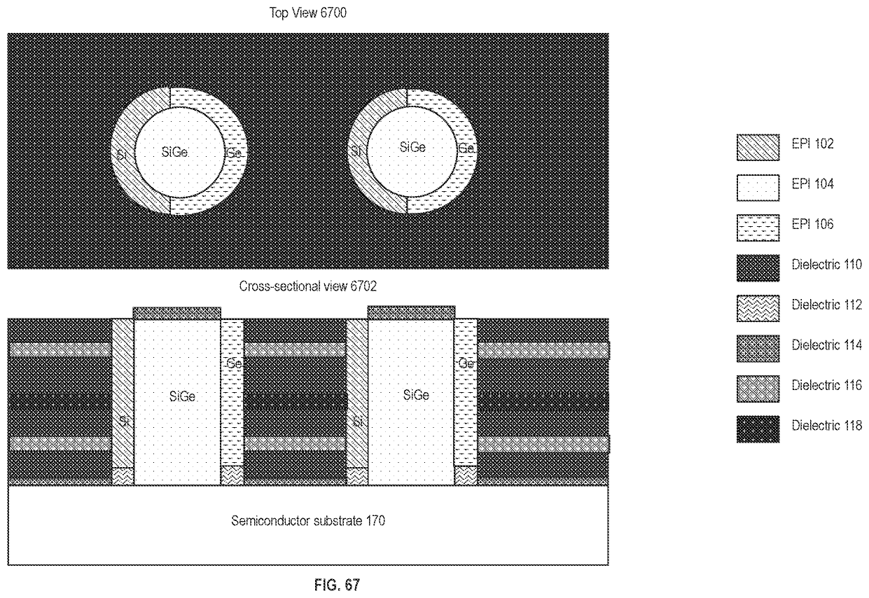

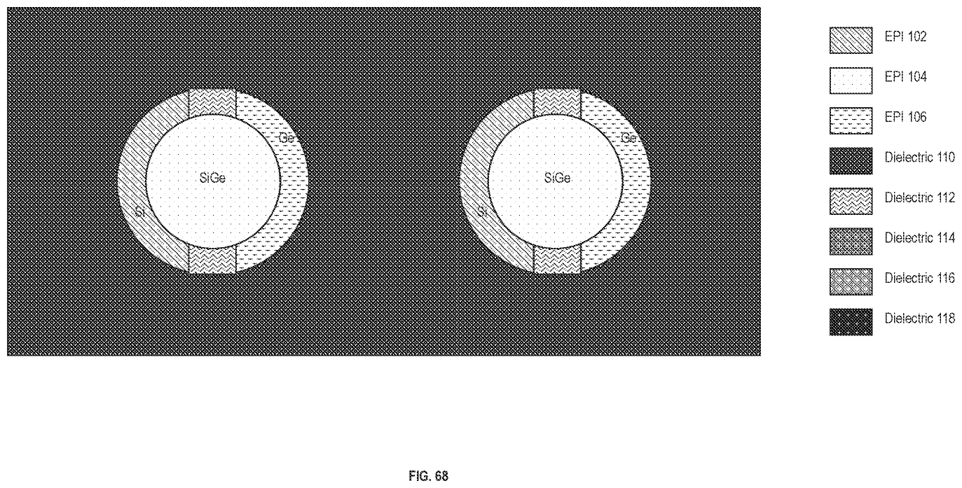

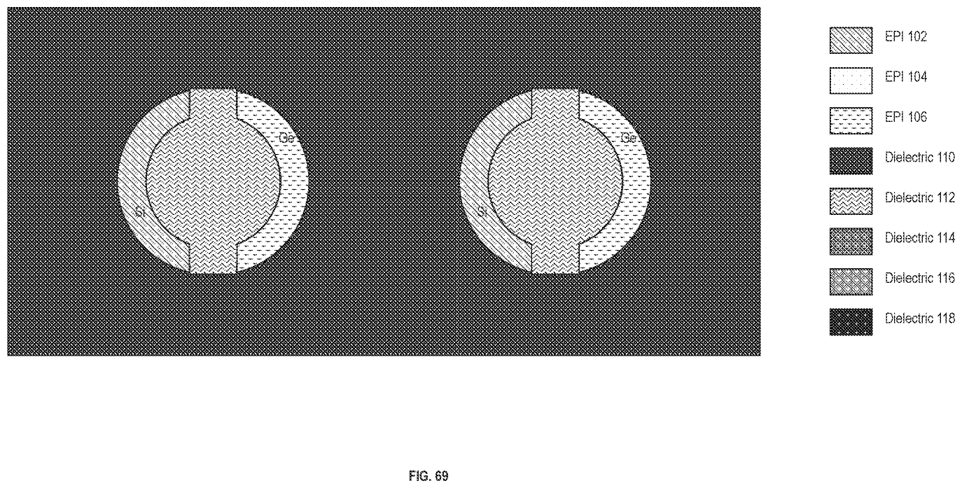

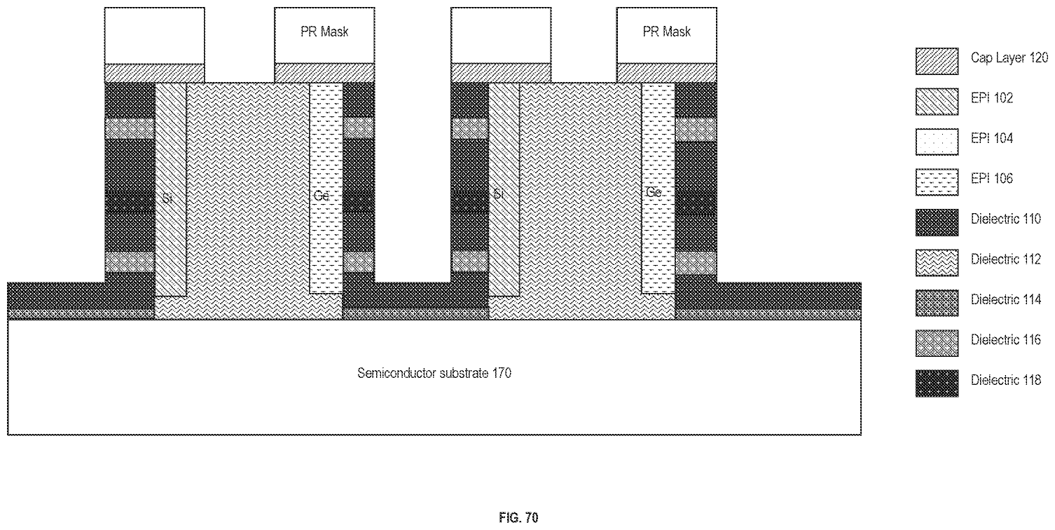

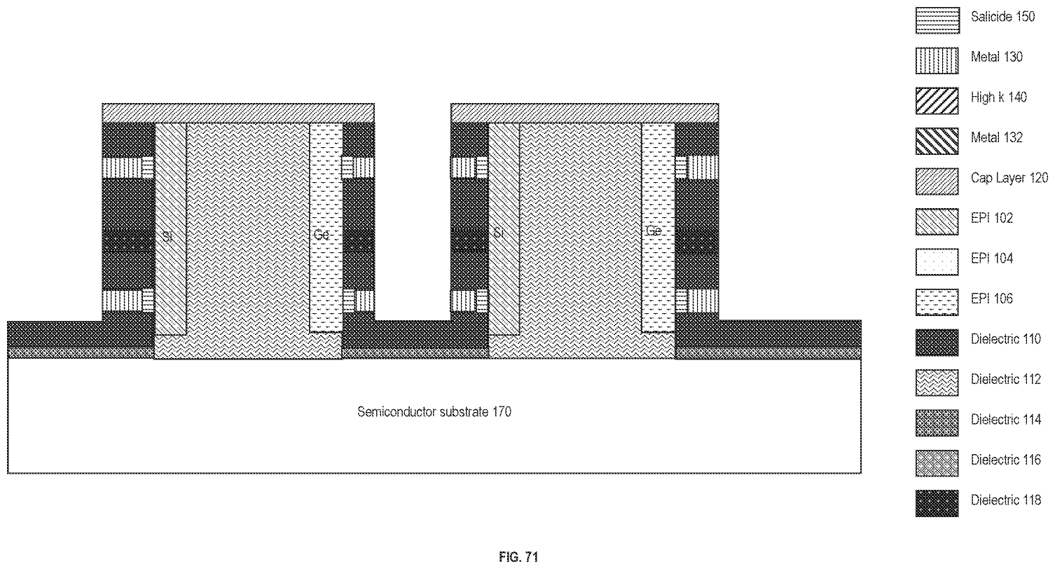

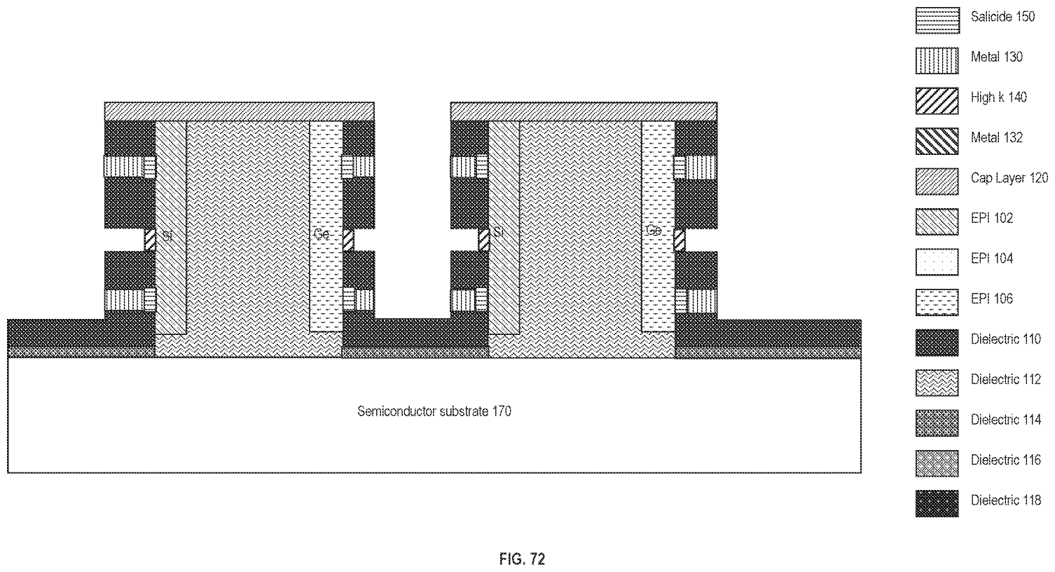

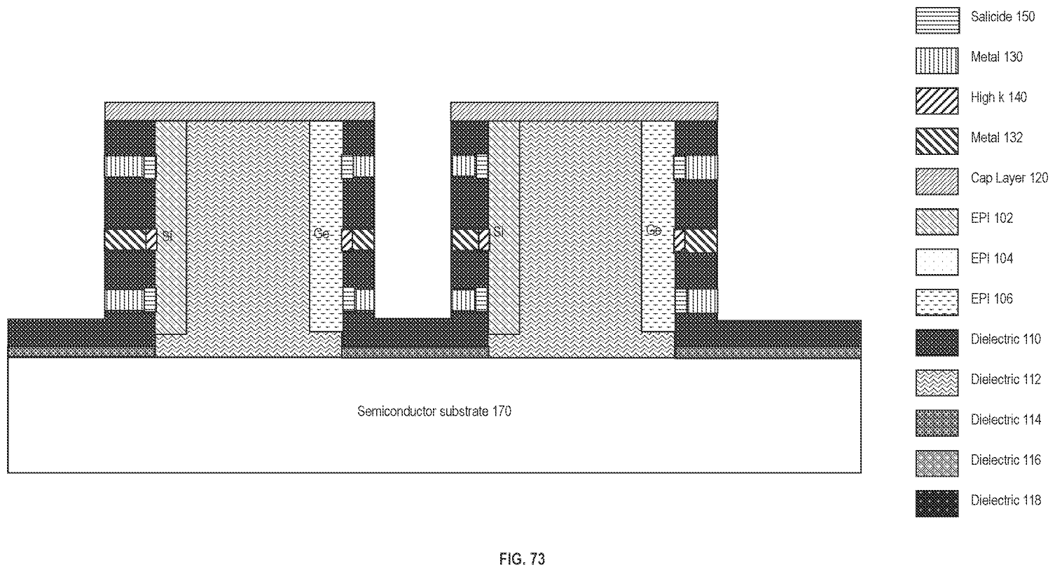

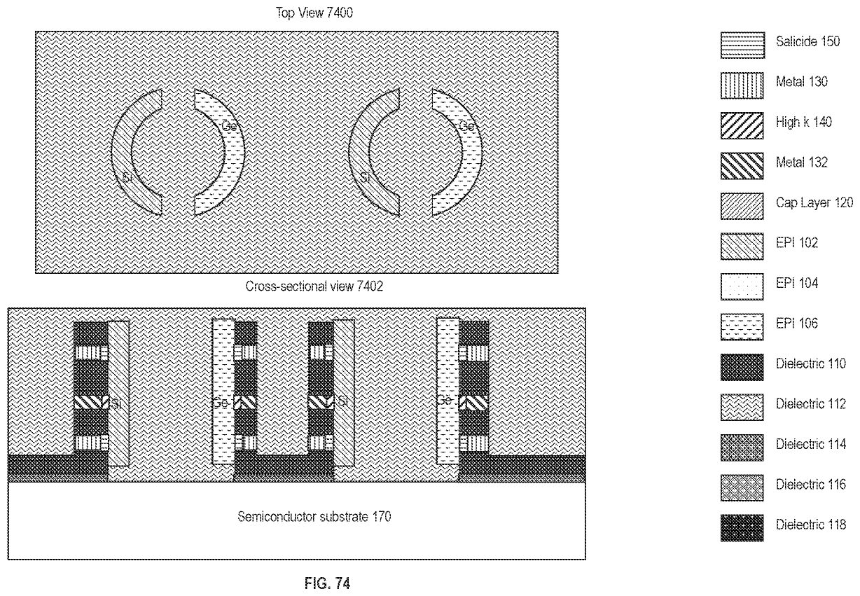

The present solution provides multiple process flows and example designs. The techniques shown in individual example and non-limiting embodiments may be combined, depending on the given application. For example, one process flow illustrates a 3D vertical nanosheet starting with a vertical EPI silicon core with oxide cylinder ring. Subsequent horizontal cylindrical silicon-germanium (“SiGe”) growth results in a SiGe cylindrical 3D vertical nanosheet with 3D isolation, as illustrated, for example, in FIGS. 3-11. In another example, a process flow illustrates a 3D vertical nanosheet starting with a vertical epitaxially grown (“EPI”) SiGe Core with oxide cylinder ring. Subsequent horizontal cylindrical silicon (“Si”) growth results in a Si cylindrical 3D vertical nanosheet with 3D isolation, as illustrated, for example, in FIGS. 12-20. In another example, a process flow illustrates a 3D vertical nanosheet starting with a vertical EPI germanium (“Ge”) core with oxide cylinder ring. Subsequent horizontal cylindrical SiGe growth results in a SiGe cylindrical 3D vertical nanosheet with 3D isolation, as illustrated, for example, in FIGS. 21-29. In another example, a process flow illustrates a 3D vertical nanosheet starting with a vertical EPI SiGe Core with oxide cylinder ring. Subsequent horizontal cylindrical SiGe growth results in a Ge cylindrical 3D vertical nanosheet with 3D isolation, as illustrated, for example, in FIG. 30. In another example, a process flow illustrated a technique in which any two selective EPI materials can be used to form 3D vertical nanosheet(s) starting with a vertical EPI 1 core with an oxide cylinder ring. This can be followed by a sequence to enable horizontal cylindrical EPI 3 growth to result in a Ge cylindrical 3D vertical nanosheet with 3D isolation, which can be done in accordance with examples illustrated in FIG. 31. In another example, a process flow illustrates a 3D vertical nanosheet starting with vertical EPI SiGe Core with oxide cylinder ring. Subsequent steps enable half-horizontal (“½ horizontal) cylindrical silicon growth and a ½ horizontal cylindrical germanium (Ge) growth for CMOS application in the split cylinder configuration with 3D isolation, as illustrated, for example, in FIGS. 32-42. In another example, a process flow illustrates a selective 3D vertical nanosheet starting with vertical EPI SiGe core with oxide cylinder ring. Subsequent steps enable ½ Horizontal Cylindrical Silicon growth and ½ horizontal cylindrical Ge growth for CMOS application in the split cylinder configuration with 3D isolation, as illustrated, for example, in FIGS. 43-59. In another example, a process flow illustrates a metal last option with the preceding example process flow, such as a split gate using, for example, Si material for NMOS and Ge for PMOS, although any other materials can be used for the same purpose instead, as illustrated, for example, in FIGS. 60-75.

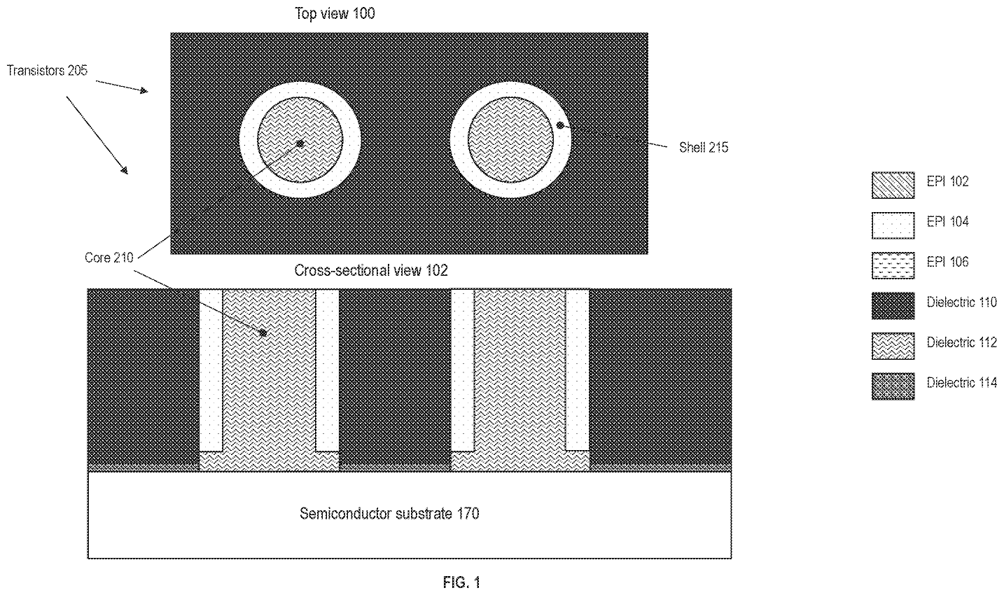

Prior to describing the fabrication steps for manufacturing the present solution, it may be useful to first briefly overview example 3D structures fabricated in accordance with the methods and techniques of the present solution. FIG. 1 includes top view 100 and cross-sectional view 102, illustrating an example structure comprising semiconductor device 205, such as a transistors, formed around a core 210 that is at least partially enclosed or surrounded by a shell 215. As shown in cross-sectional view 102, transistors 205 are formed on a semiconductor substrate 170, although any other substrate can be used instead.

Core 210 of device 205 in FIG. 1 is formed by a dielectric 112. The base of the core 210 that is closer to the substrate 170 is wider than the top of the core 210. In the illustrated example, core 210 is at least partially cylindrically shaped and extends vertically (e.g., orthogonally) from the plane of the substrate 170. The length of the core 210 (e.g., along its vertical extension with respect to the plane of the substrate) is larger than its width (e.g., the diameter of the top intersection of the core 210. Cross-section of a core 210 is illustrated as a circle, although it is understood that its cross-section can also be elliptical, triangular, square, rectangular, pentagonal, hexagonal, hexagonal, decagonal or have shape of any other polygon. Core 210 can be fabricated from a dielectric, a semiconductor material or a combination of the two. For example core 210 can be epitaxially formed and one or more shells 215 can be grown upon the epitaxially grown core 210. Once epitaxially grown shell 215 is grown upon the epitaxially grown core 210, the core 210 or a portion of the core 210 can be replaced by a dielectric core 210.

Surrounding, encircling or partially or fully enclosing the core 210 from one or more sides is the shell 215. The shell 215 can comprise a layer of material coated or deposited on the outer surface of the core 210. For example, the shell 215 can be formed by depositing a layer of material on the curved outer surface on the sidewall of the cylindrical core 210. Shell 215 can be formed by epitaxially growing doped semiconductor material on the sidewall(s). Additionally or alternatively, the shell 215 may comprise a 2D material or a semiconductive behaving semiconductor and may be deposited using atomic layer deposition (ALD) or other suitable technique. Shell 215 can have a cross-section whose inner surface is defined by the outer surface of the sidewall of the core 210, and whose outer surface can be circular, elliptical or polygonal and having any number of sides.

FIG. 1 illustrates an example of an implementation in which one or more vertical shell structures are provided and in certain vertical channels are demonstrated. In certain embodiments, a first and second transistors are provided such that the backsides of the channels (i.e., the side opposite the gate structure) for each device face each other. As will be detailed below, this is the result of the structures being formed around a common preform, mandrel, post, or shape as will be described in more detail below.

In FIG. 1, the shell 215 can be referred as the vertical shell 215, as its length is oriented vertically with respect to the substrate 170. The material used to form the shell 215 can include EPI 104 (e.g., the epitaxially grown material). The vertical shell 215 has a surface that follows a generally circular cross-section of the core 210 and has a length extending orthogonally with respect to the plane of the substrate upon which it is formed and/or the plane of the material layers deposited on the substrate in which it is formed.

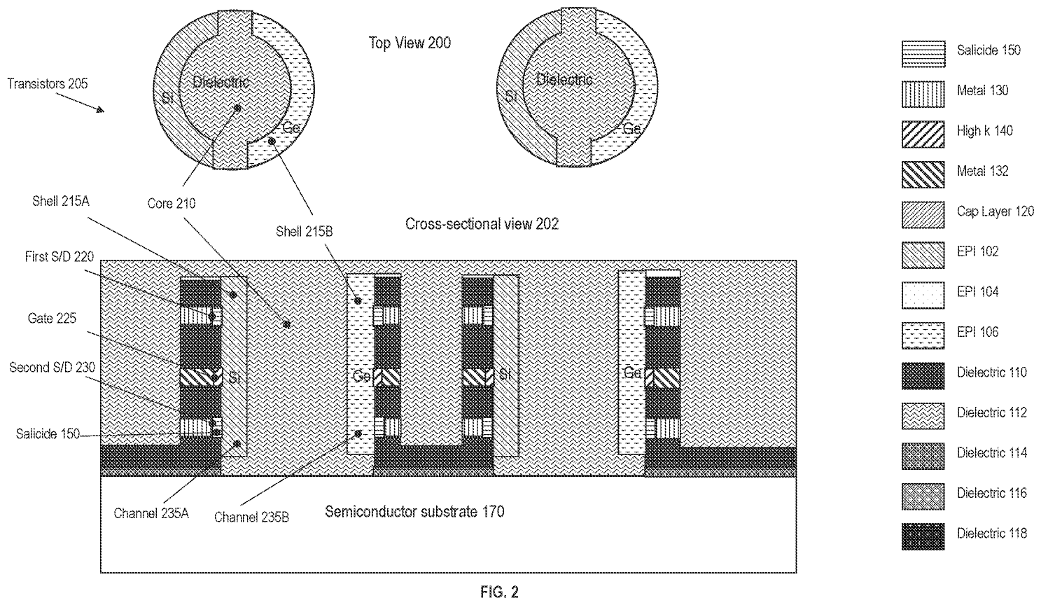

The EPI 104 vertical shell 215 may comprise an epitaxially grown semiconductor material that surrounds a dielectric core 210 that can be formed with dielectric 112 material. In some instances, such as in FIG. 2, a single core 210 may carry or support multiple shells 215, each one of which can cover a portion of the outer surface of the core 210. Adjacent shells 215 may be isolated from each other by dielectric 110 material that can be deposited between the shells or on the outer surfaces of the shells 215. The vertical shell 215 may be provided on a substrate 170, such as a semiconductor substrate and the shells may be isolated from the substrate by dielectric 112 as shown in cross-sectional view 102.

FIG. 2 illustrates a schematic of an implementation in which multiple vertical channel transistor devices 205 are provided in an array. For example, a single core 210 can support multiple shells 215, each one of which is, comprises or forms its own channel 235 for a separate transistor device 205. Therefore, FIG. 2 can correspond to an embodiment in which each of the two illustrated cores 210 form a single transistor 205 having two channels 235 formed by two shells 215A and 215B on each of the cores 210. Alternatively, FIG. 2 can correspond to an embodiment in which the two cores 210 support four transistors 205, such that each core supports thereon two shells 215, each shell 215 acting as, comprising or forming its own channel 235 for the transistor 205. In certain embodiments, a first and second transistor 205 are provided such that the backsides of the channels 215A and 215B (the side opposite the gate 225 structure) for each device face each other. As will be detailed below, this is the result of the structures being formed around a common preform, mandrel, post, or shape, or otherwise core 210, as will be described in more detail below.

Each pair of transistors 205 may include two opposing semicircular shaped vertical shells 215, forming channel 235 regions, shown here as EPI 102 and EPI 106. Though two different materials are shown in FIG. 2 forming two shells 215A and 215B, a single material may be utilized instead and may be doped so as to have different or similar dopant profiles, such as for example an n-type and a p-type channel 215. Moreover, three or more different types of materials may be utilized for a given application, such that more than two channels 235 are formed around the single core 210. Each vertical channel 235 formed by shell 215 abuts two source/drain (“S/D”) contacts, which can include the first S/D contact 220 and the second S/D contact 230 of a transistor 205. The first and second S/D contacts 220/230 are shown being formed using metal 130. In some embodiments, the transistor device 205 can include salicide 150 in the S/D contacts 220/230, at the interfaces between the metal and the semiconductor shells/channel 215, which can be formed via annealing. Located between the S/D regions 220/230 is an isolated gate 225 structure comprising a high k 140 material and a conductor material, which in the illustrated embodiment is shown being formed with metal 132. It is understood that that the S/D contacts 220/230 and the gate 225 can be formed using the same or a different metals or other electrically conductive materials.

The top view of structure in FIG. 2 shows the curvature of the two channel 215 regions as well as the isolation of the two channel 215 regions from each other. More specifically, the shells 215A and 215B, and therefore their corresponding channels 235A and 235B are isolated from each other with an intervening dielectric 112. Connections to the S/D contacts 220/230 and gate 225 regions are shown as examples, but it will be appreciated that conductive interconnects can be provided according to various designs and conventional techniques.

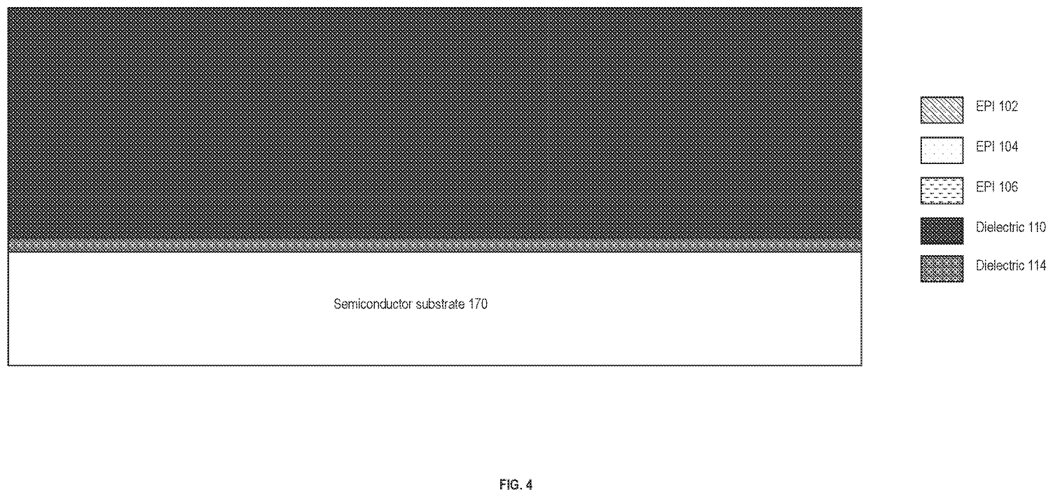

FIG. 3 summarizes the steps performed in FIGS. 4-11. The diagram of FIG. 3 can be used to illustrate some of the variations in order to simplify the number of schematic drawings used to present some example variations. As shown in FIG. 3, device 205 can be formed in five steps. At the first step of FIG. 3, Si EPI 102 can be grown as a 3D vertical preliminary core 208 with its oxide shell comprised of dielectric 112. At the second step, at least a top portion of the dielectric 112 shell can be removed from the preliminary oxide shell, subsequent to which, at the third step, SiGe EPI 104 material can be epitaxially grown to fill in the space left by the removed dielectric 112 and form the permanent shell 215 of the transistor 205 structure. At the fourth step, Si EPI 102 core can be removed, leaving the shell 215 standing without the preliminary core 208. At the fifth step, the space left behind by removing the preliminary core 208 material can be filled back again using dielectric 112 material, thereby reforming the device 205 with its permanent and final core 210 and its surrounding shell 215 that can act as, comprise or form the channel 235 of a transistor 205, depending on the design.

A first process flow for making the shell structure will now be set forth. Referring now, for example, to FIGS. 3-11, an example set of fabrication steps for manufacturing a structure similar to the one shown in FIG. 1 is illustrated. In brief overview of FIG. 4, multiple dielectric layers (dielectric 114 and dielectric 110) are formed on a semiconductor substrate 170. The dielectrics may be selected to be selectively etched relative to each other for reasons that will become clear as the process is explained. As illustrated in FIG. 4, a layer of dielectric 114 is formed or deposited on semiconductor substrate 170, on top of which a thicker layer of dielectric 110 is formed.

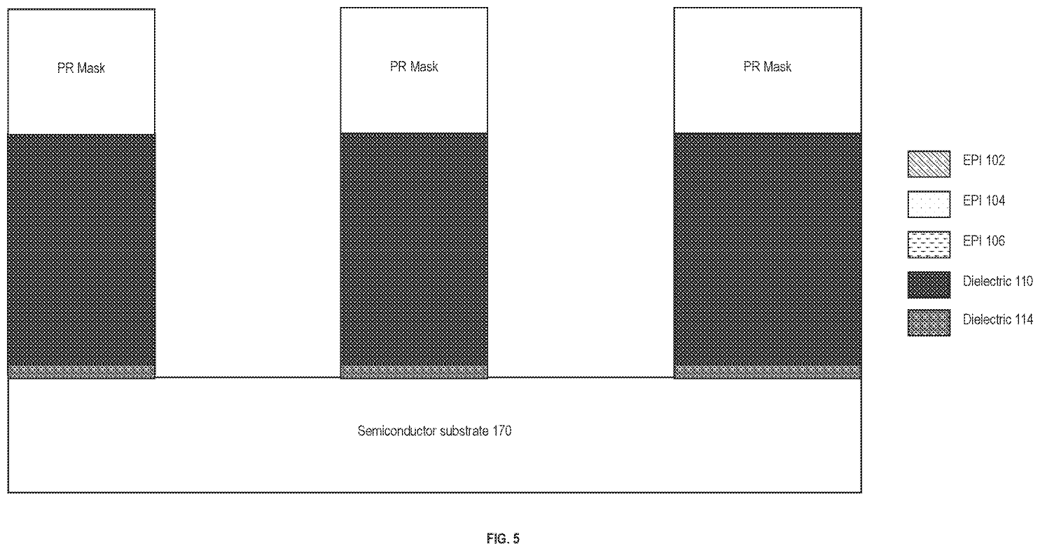

As shown in FIG. 5, a photoresist mask (PR mask) is used to for patterning and an anisotropic etch is utilized to remove portions of dielectrics 110 and 114 to expose the underlying semiconductor substrate 170.

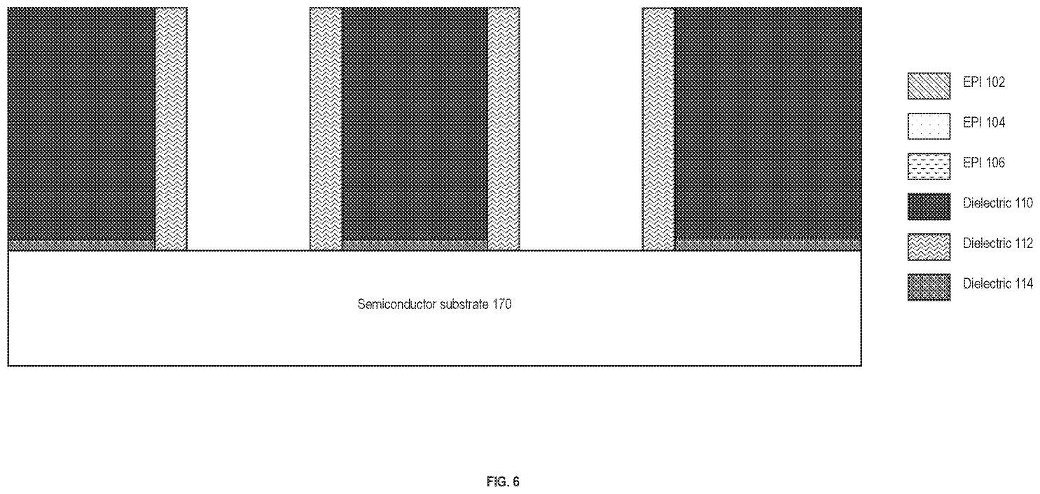

As shown in FIG. 6, the PR mask is removed followed by a formation of a spacer of dielectric 112 that can be formed by a deposition, which can then be followed by directional etch to leave material along the sidewalls of the opening. Dielectric 112 may be selected to be selectively etchable relative to dielectrics 110 and 114. As an example, dielectric 110 may be silicon oxide, while dielectric 112 may be silicon nitride, and dielectric 114 may be silicon oxynitride or silicon carbide.

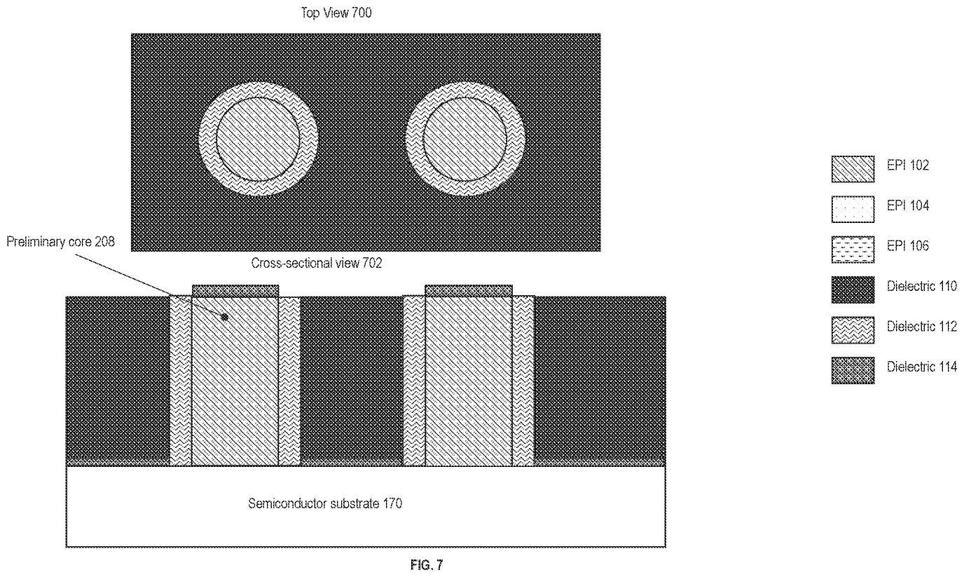

FIG. 7 shows the vertical growth of a layer via an epitaxial process to form EPI 102. For example, Si material may be used as EPI material, although SiGe, Ge or other materials can be used, depending on the design. EPI 102 material can be epitaxially formed on a silicon semiconductor substrate according to conventional growth techniques to form a preliminary core 208, which can later be replaced by core 210. This can be followed by the selective formation of a dielectric 114 cap to protect the underlying EPI 104 region.

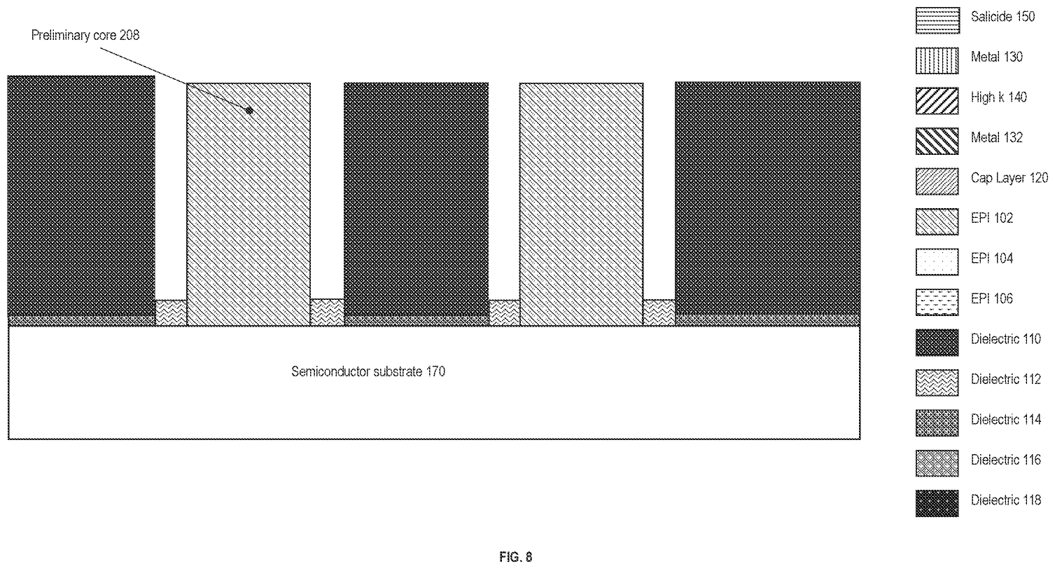

FIG. 8 illustrates a process in which an etch is performed to remove a portion of dielectric 112 surrounding the EPI 102 formed preliminary core 208. The remaining portion of dielectric 112 will serve as an isolation between the semiconductor substrate and the yet-to-be formed epitaxial layer that will overlay the remaining portion of dielectric 112.

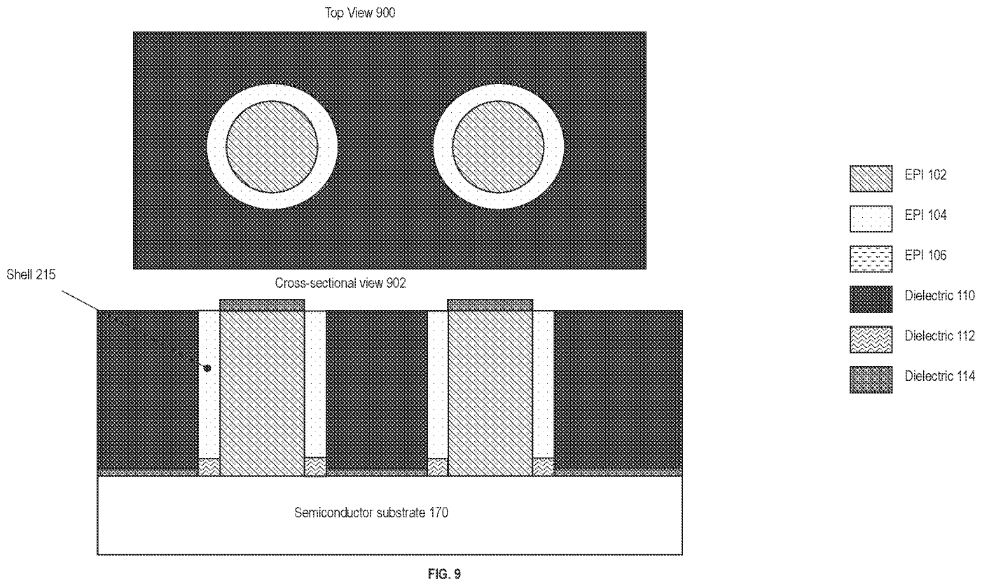

As shown in FIG. 9, a layer (EPI 104) is epitaxially grown in the trenches created in FIG. 8 and therefore formed on the sidewalls of the EPI 102 layer as shell 215. As an example, a SiGe layer may be epitaxially grown as EPI 104, although Si, Ge or other materials can be used, depending on the design. The layer is isolated from the underlying semiconductor substrate by the remaining dielectric 112 in the opening.

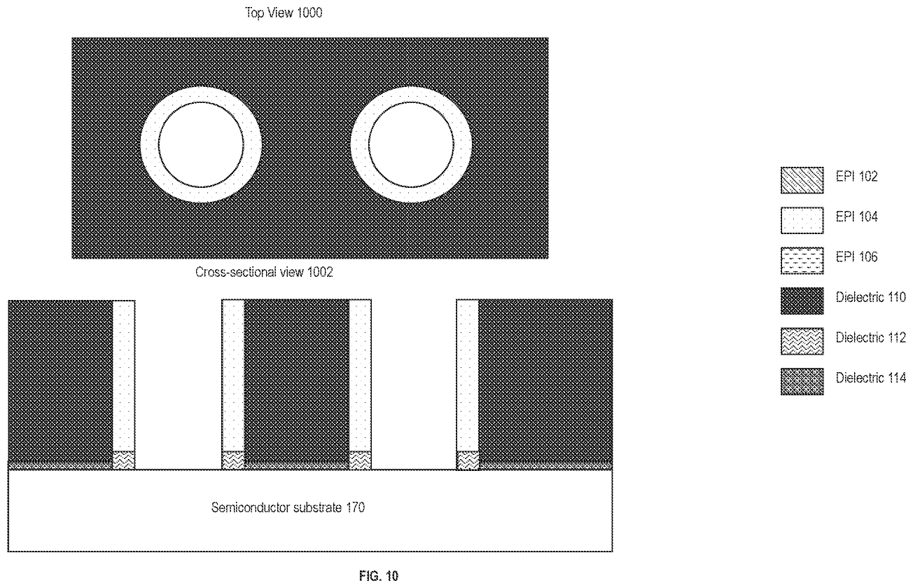

As shown in FIG. 10, the cap may be removed by etching or performing a CMP and the EPI 102 layer may be removed by an etch process that etches EPI 102 without significantly etching EPI 104. Thus, EPI 104 is fully isolated from the underlying semiconductor substrate. In some embodiments, a layer of dielectric material may be left remaining on top of the substrate.

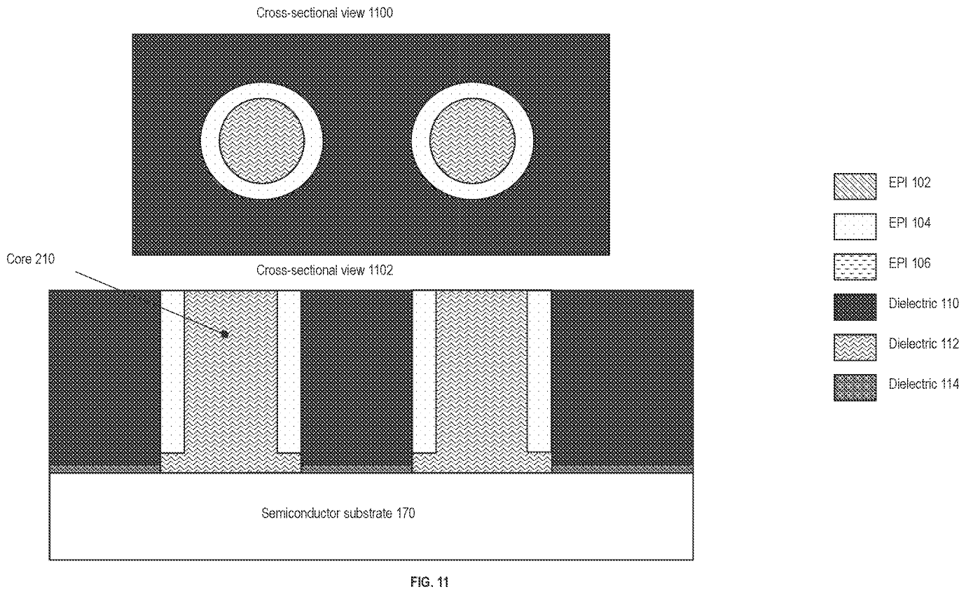

As shown in FIG. 11, the resultant structure may be filled by dielectric 112 further isolating the shell 215 of EPI 104 material. By filling the cavity that was previously occupied by preliminary core 208, a (final) core 210 is formed for the transistor 205. The shell 215 around the core 210 may be utilized for various purposes, such as part of a transistor structure as will be described in further detail below.

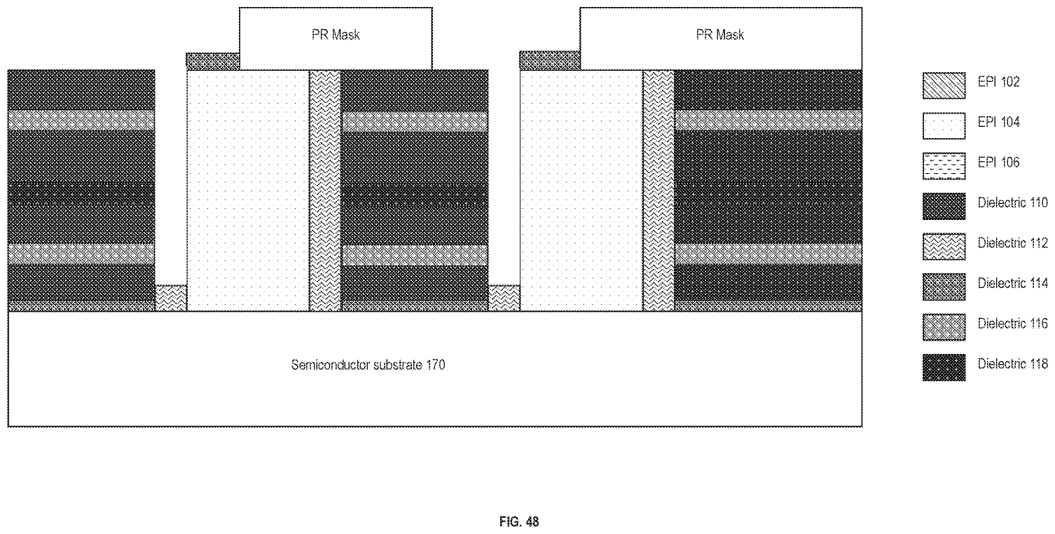

Moreover, following the steps illustrated in FIGS. 3-11, additional one or more steps can be added (not shown) after the fifth step, in which a trench is formed to segment the single epitaxial shell 215 into multiple electrically isolated shells 215 around the same core 210. Examples of such additional steps are discussed below, where multiple separated shells 215 can be formed to serve as channels 235 around a single core 210 to form one or more transistors 205. In the examples discussed later in connection with FIG. 48-59 or 64-75, for example, two shell/channel portions can be formed around a single core 210, without deviating from the intended structure and techniques.

Other examples, such as those illustrated in connection with FIGS. 12, 21 and 30 for example, can provide additional illustrate alternatives for forming different epitaxial shells using different core epitaxial layers. For example, materials for EPI layers (e.g., 102, 104 and 106) can be swapped or be used interchangeably with different dielectrics (e.g., 110, 112, 114, 116 and 118) to form different combinations of core 210 and shells/channels 215.

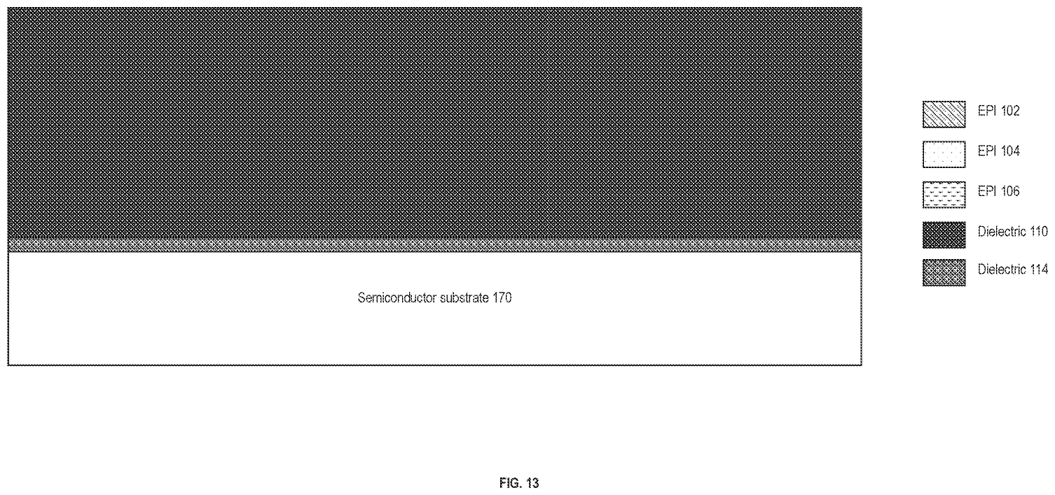

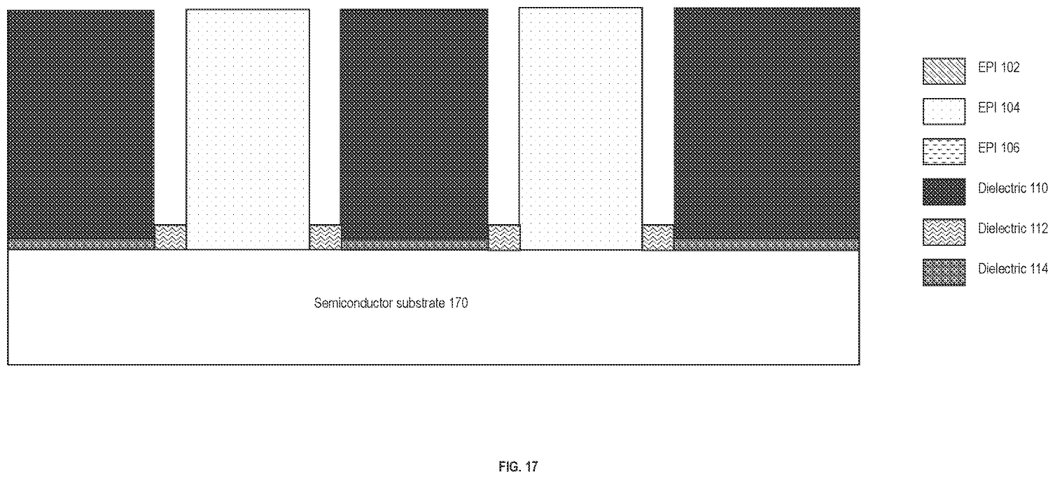

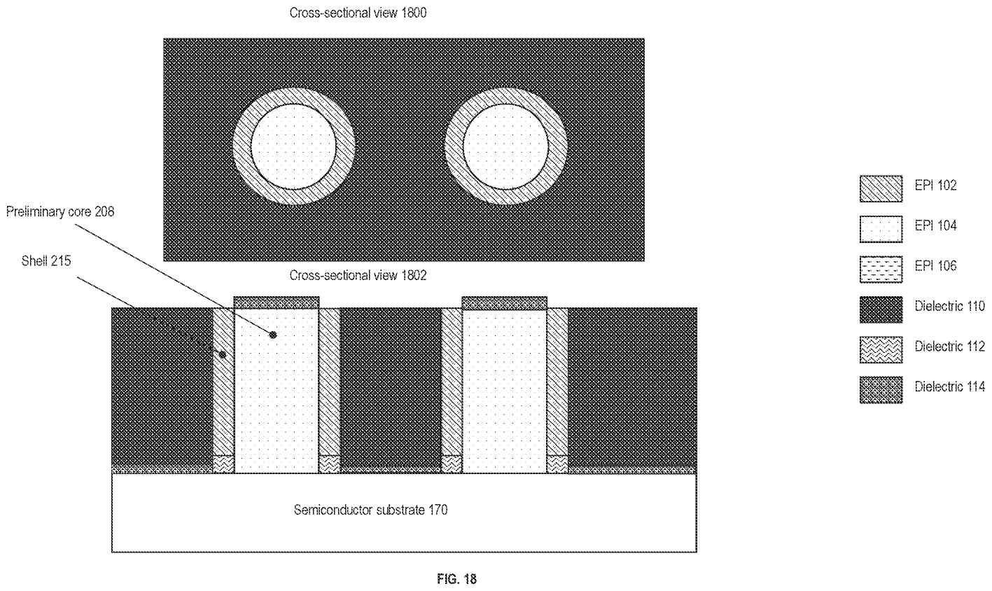

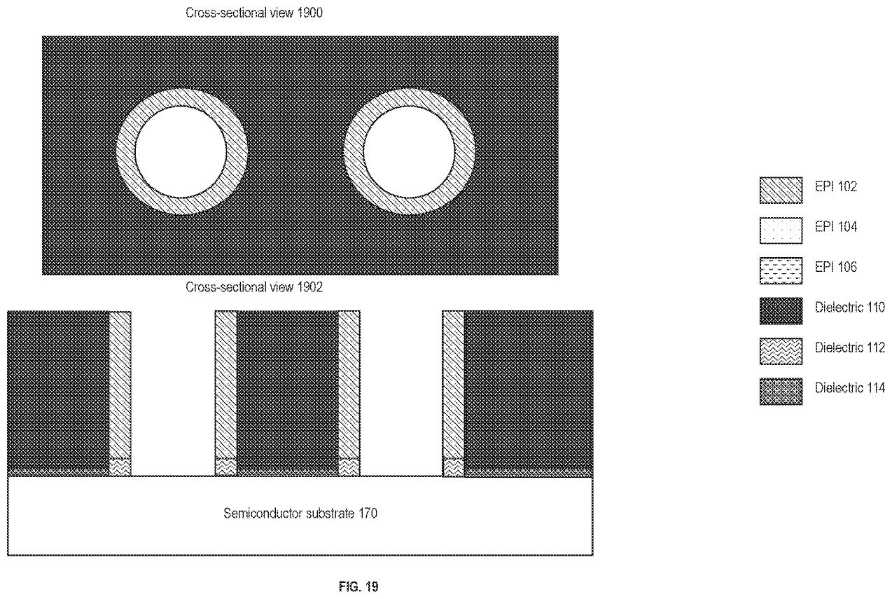

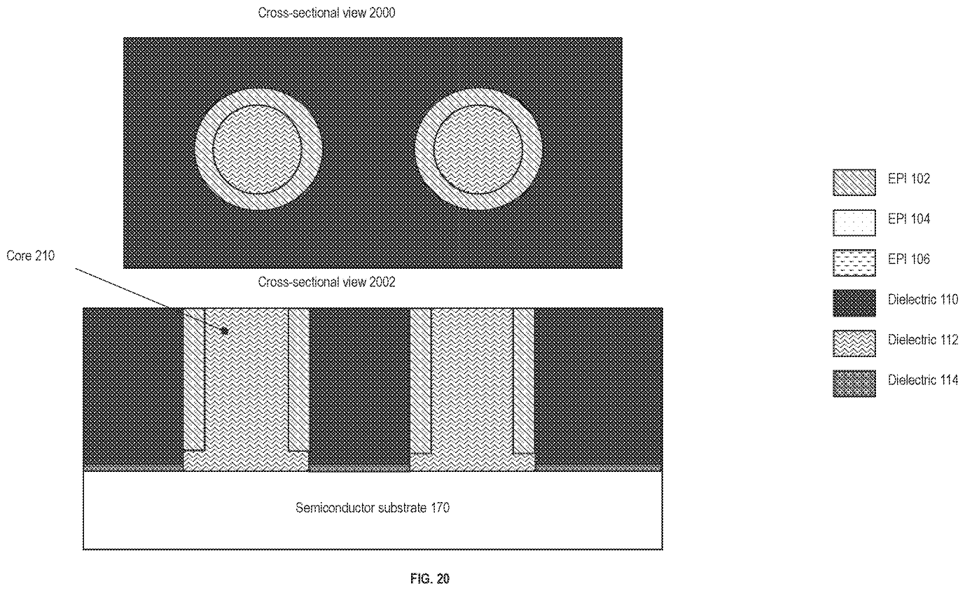

In FIGS. 12-20, a similar configuration as discussed in connection with FIGS. 3-11 is illustrated in which a different set of materials are used to form the device 205. For example, similar to FIG. 3, in FIG. 12, a diagram of five steps for forming a transistor 205 is illustrated. At the first step, SiGe EPI 104 can be grown as a 3D vertical preliminary core 208 with its oxide shell comprised of dielectric 112, as illustrated in FIGS. 13-16. Techniques to implement this are discussed, for example, in connection with FIGS. 4-7. At the second step, shown in FIG. 17, at least a top portion of the dielectric 112 shell can be removed from the oxide shell, using techniques discussed in connection with FIG. 8. Then, at the third step, Si EPI 102 material can be epitaxially grown to form the shell 215 instead of the removed dielectric 112, as shown in FIG. 18 and discussed in connection with FIG. 9. At the fourth step, SiGe EPI 104 preliminary core 208 can be removed, as shown in FIG. 19, leaving the shell 215 standing without the preliminary core 208, using steps discussed in connection with FIG. 10. At the fifth step, as shown in FIG. 20, the space left behind by removing the preliminary core 208 material can be filled back again using dielectric 112 material, which is further discussed in connection with FIG. 11. These five steps can therefore be used to reforming the device 205 using a core 210 and its surrounding shell 215 that can act as, comprise or form the channel 235 of a transistor 205.

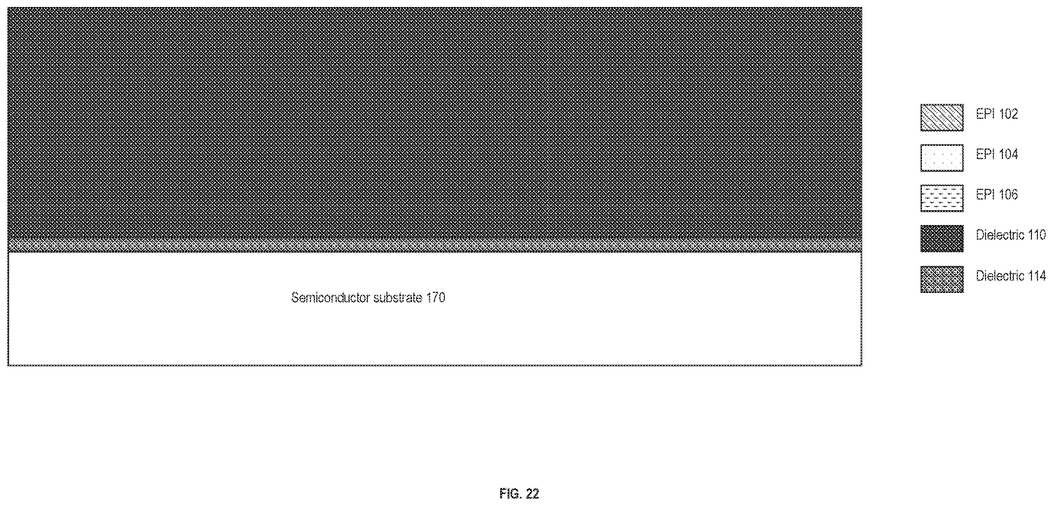

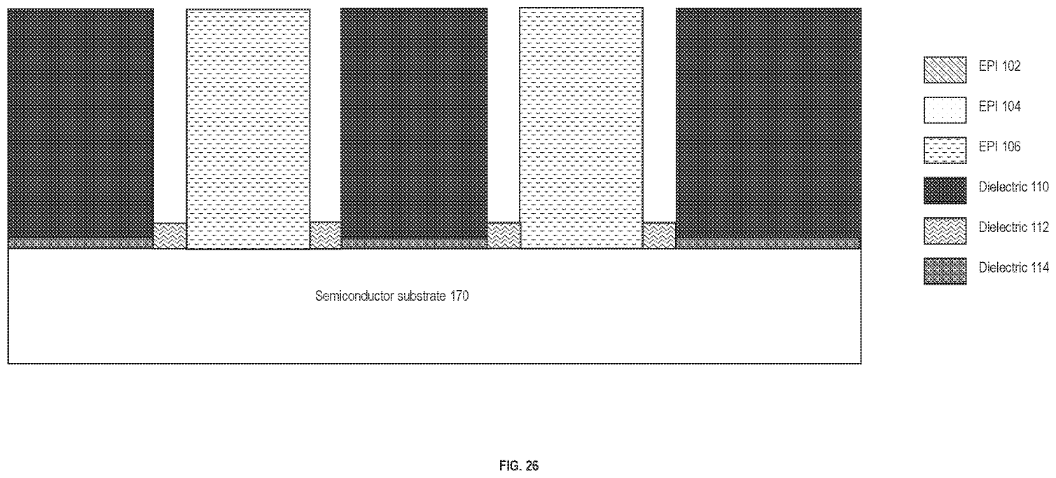

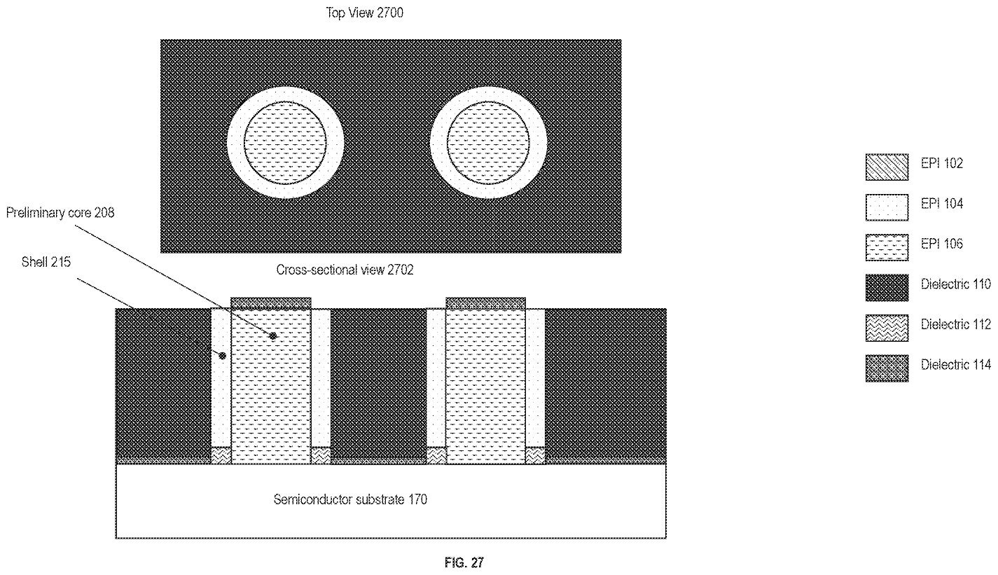

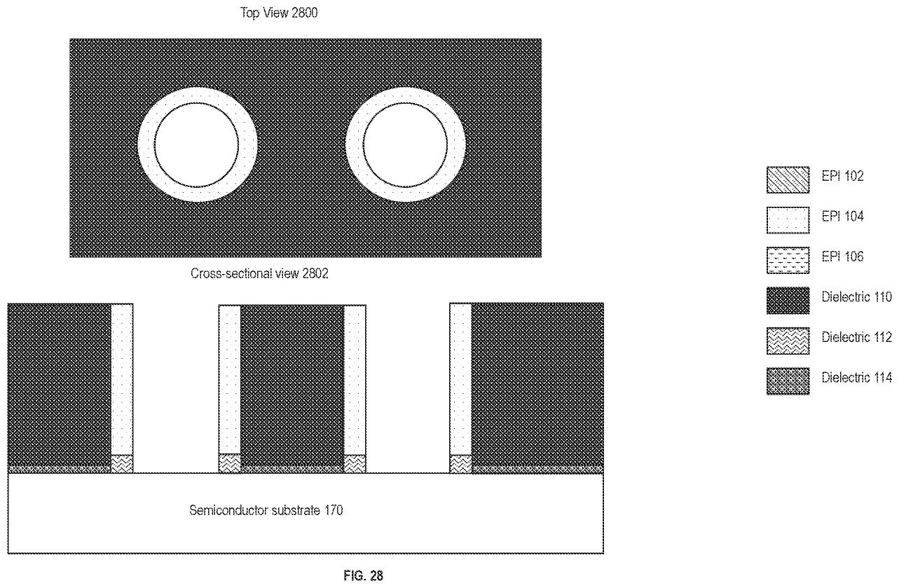

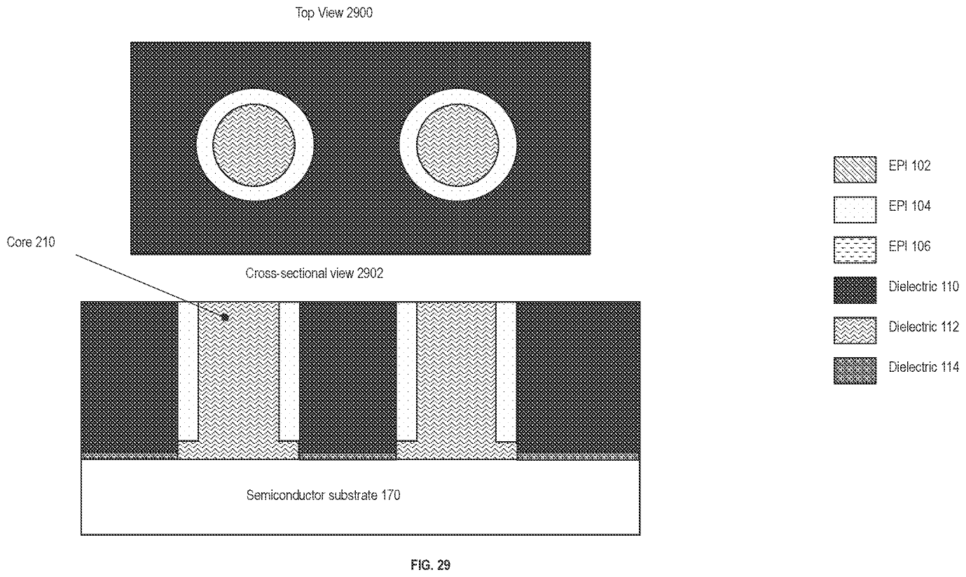

In FIGS. 21-29, a similar configuration as discussed in connection with FIGS. 3-11 and FIGS. 12-20 is illustrated in which a different set of materials are used to form the device 205. For example, similar to FIG. 3, and FIG. 12, in FIG. 21, a diagram of five steps for forming a transistor 205 is illustrated. At the first step, Ge EPI 106 can be grown as a 3D vertical preliminary core 208 with its oxide shell comprised of dielectric 112, as shown in FIGS. 22-25. Techniques to implement this are discussed, for example, in connection with FIGS. 4-7. At the second step, shown in FIG. 26, at least a top portion of the dielectric 112 shell can be removed from the oxide shell, using techniques discussed in connection with FIG. 8. Then, at the third step, Ge EPI 106 material can be epitaxially grown to form the shell 215 instead of the removed dielectric 112, as shown in FIG. 27 and discussed in connection with FIG. 9. At the fourth step, Ge EPI 106 preliminary core 208 can be removed, as shown in FIG. 28, leaving the shell 215 standing without the preliminary core 208, using steps discussed in connection with FIG. 10. At the fifth step, as shown in FIG. 29, the space left behind by removing the preliminary core 208 material can be filled back again using dielectric 112 material, which is further discussed in connection with FIG. 11. These five steps can therefore be used to reforming the device 205 using a core 210 and its surrounding shell 215 that can act as, comprise or form the channel 235 of a transistor 205.

In FIG. 30, an example of top down illustrations and their corresponding series of steps is provided to illustrate one of the example variations of a process flow in which a single shell is formed around a core 210 structure. Similar to the discussion above in connection with FIGS. 3, 12 and 21, in the first step, a SiGe EPI 104 3D vertical core 210 can be formed upon a substrate. For example, SiGe EPI 104 material can be epitaxially grown to form the initial core 210, while a dielectric 112 can be used to form an initial shell surrounding the sidewalls of the SiGe EPI 104 core 210. Then, the surrounding oxide shell (e.g., dielectric 112) can be removed, optionally leaving only a thin layer of dielectric 112 oxide for isolation from the substrate. In some embodiments however, the initial shell material (e.g., dielectric 112 in the illustrated example) can be removed entirely to reach the substrate. Then, Ge EPI 106 can be epitaxially grown as a new 3D shell around the SiGe EPI 104 core 210. Then, the central portion of the structure (e.g., SiGe EPI 104 core 210) can be removed or etched, leaving only the Ge EPI 106 shell. Finally, the central portion (e.g., core 210) can be rebuilt using dielectric 112. After the steps are completed, the final structure can include a dielectric 112 core 210 and single cylindrical shell 215 made from Ge EPI 106 material, forming a ring around the core 210. As a result, the resulting shell 215 comprises epitaxially grown Ge material and dielectric 112 may be deposited for electrical isolation or other processing steps. FIG. 30 structure can be implemented using the same or similar techniques such as those discussed in connection with FIGS. 3-11.

Just like with FIG. 30 above, FIG. 31 also provides an example of top down illustrations and their corresponding series of steps of a process flow in which a single shell is formed around a core 210 structure using a different set of materials. In FIG. 31, first a Si EPI 102 vertical core 210 can be formed upon a substrate. For example, Si material can be epitaxially grown to form the initial core 210, while a dielectric 112 can be used to form an initial shell surrounding the sidewalls of the Si core 210. Then, the surrounding oxide shell (e.g., dielectric 112) can be removed, optionally leaving only a thin layer of dielectric 112 oxide for isolation from the substrate, or being removed entirely exposing the substrate beneath. Then, SiGe EPI 104 can be epitaxially grown as a new 3D shell around the Si EPI 102 core 210. Then, the central portion of the structure (e.g., Si EPI 102) can be removed or etched, leaving only the SiGe EPI 104 shell. Finally, the central portion (e.g., core 210) can be rebuilt using dielectric 112. After the steps are completed, the final structure can include a dielectric 112 core 210 and single cylindrical shell 215 of SiGe EPI 104 that forms a ring around the core 210. FIG. 31 structure can be implemented using the same or similar techniques such as those discussed in connection with FIGS. 3-11, swapping only the relevant core and shell materials, as shown in the illustrations. Similarly, structures implemented in FIGS. 12-20 and 21-29 can also be similarly implemented using the same or similar techniques as those discussed in FIGS. 3-11, keeping in mind only to swap the relevant core and shell materials, as shown in the illustrations.

In FIG. 3, the initial shell 215 included Si. After removing the dielectric (oxide shell) a SiGe layer is grown. The Si core is then removed and dielectric 112 can be deposited for isolation or other processing steps. As a result, the final shell 215 comprises epitaxially grown SiGe material, using the same or similar techniques such as those discussed in connection with FIGS. 3-11 and/or 12-20. In FIG. 21, the initial shell 215 included Ge and after completing the above-discussed process, the final resulting shell 215 comprises epitaxially grown SiGe material, and this structure can be formed using the techniques discussed in FIGS. 3-11 and/or 12-20. Therefore, the example structure, and its materials shown in FIGS. 3-11 are intended to be an example and not a limited design, which can ultimately utilize any combination of the EPI, dielectric, metal and other materials discussed herein.

Additionally or alternatively, multiple different epitaxial layers may be formed on the same epitaxial core. Such a process is detailed with reference to the figures below for one combination of materials. As with FIGS. 3, 21 and 30, multiple variations with different material combinations are contemplated with only one example shown for the sake of brevity.

In some example designs, devices 205 can be formed with multiple separate shells 215 or channels 235 formed around a core 210. More specifically, a single core 210 can support multiple shells 215, which can form channels 235 for one or more transistors 205. For example, a transistor 205 can include a core 210 interfacing with, connecting to and/or supporting on its outer sidewall two, three, four or more shells 215. Each shell 215 can be deposited on, connected to, interface with or cover a portion of the outer surface of the core 210. Shells 215 can be electrically isolated from each other by an empty space or by an intervening dielectric disposed on the outer surface of the core 210 and in between the shells 215. In some embodiments, the plurality of shells 215 on a single core 210 can form the plurality of channels 235 for a multi-channel single transistor 205. In some embodiments, the plurality of shells 215 on a single core 210 can form the plurality of transistors 205, each transistor 205 comprising one or more of channels 235 formed by one or more shells 215 that are a subset of the plurality of shells 215 on the core 210.

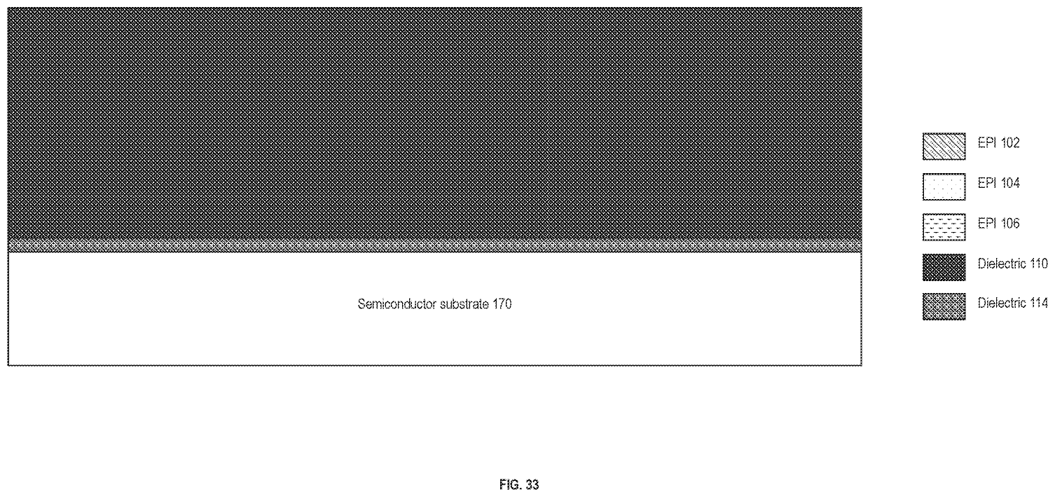

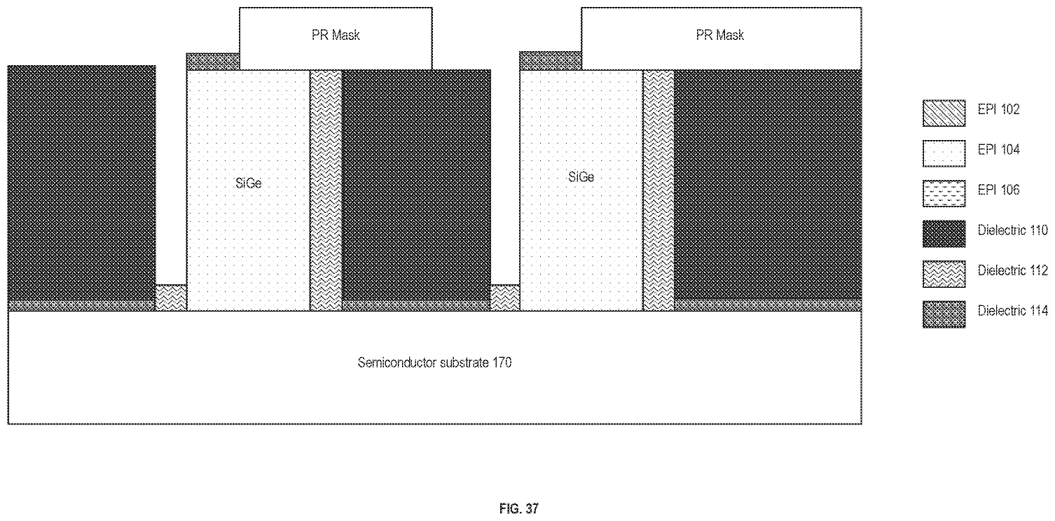

In the context of multi-shell structure design, in FIG. 32, an example is shown in which EPI material shell, such as from SiGe for example, is grown on the semiconductor substrate as was described in the examples discussed above in connection with FIGS. 3-11, 21 and 30, while dielectric is formed around the EPI core 210, such as in this case the SiGe Epi core 210, as shown for example in FIGS. 33-36 However, in this implementation, a photoresist mask (PR mask) is formed over a portion of the structure to protect a portion of the underlying dielectric 112 layer. The exposed portion of dielectric 112 is removed, e.g., by an atomic layer etch (ALE) process or other suitable removal process as illustrated in FIG. 37. As described above, a portion of dielectric 112 in the bottom of the opening is left unetched to serve as an isolation dielectric.

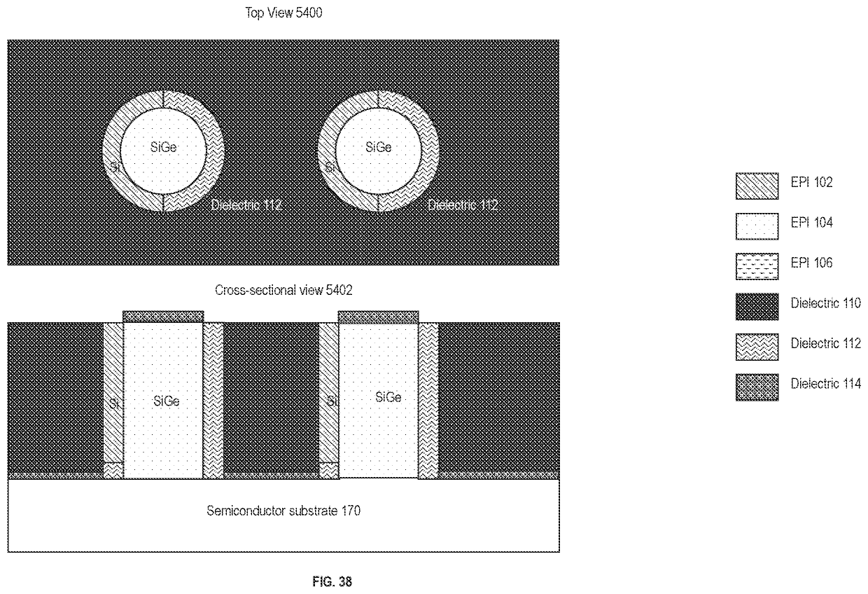

As shown in FIG. 38, which includes top view 5400 and cross-sectional view 5402, an epi layer (e.g., Si EPI 102 based shell 215) is formed on the exposed sidewall of the SiGe core 210. The PR mask is removed before or after the epi growth to expose the previously masked portion of dielectric 112.

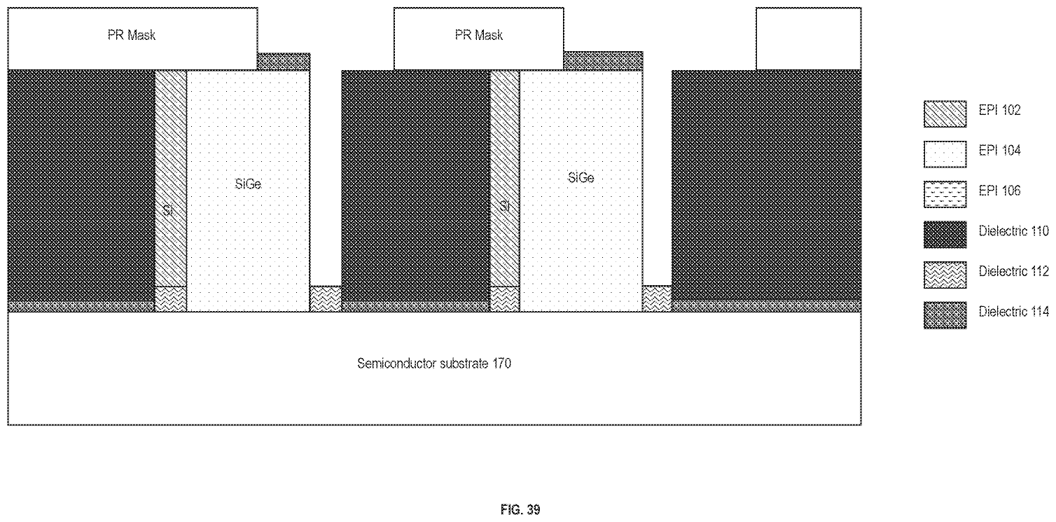

As shown in FIG. 39, a mask is formed to protect the Si EPI 102 layer. The previously masked dielectric 112 layer is removed, leaving a portion of the dielectric 112 in the bottom of the opening for isolation of the structure from the underlying semiconductor substrate.

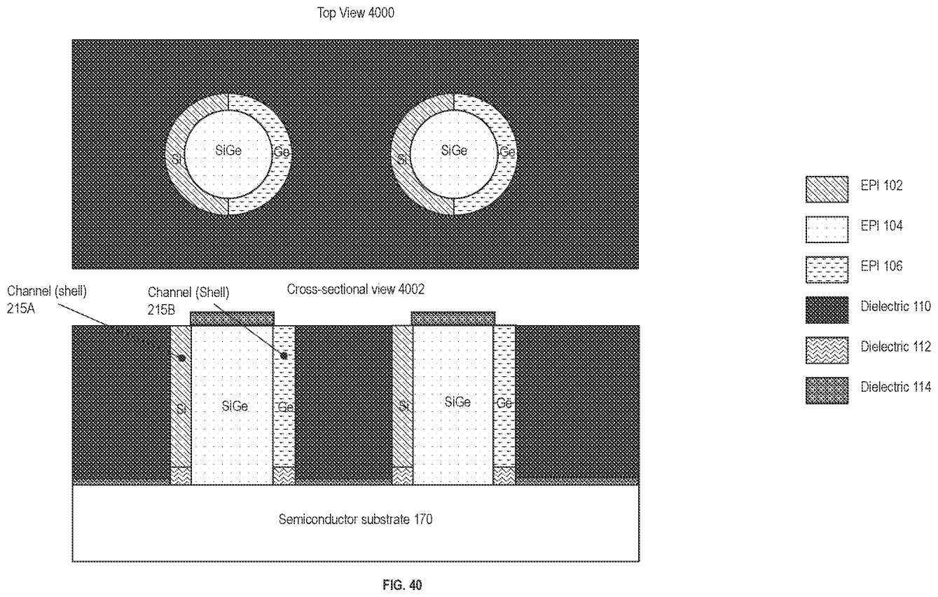

As shown in FIG. 40 that includes a top view 5600 and cross-sectional view 5602, an EPI layer (e.g., p+ doped Ge EPI 106) is formed through an epitaxial growth on the sidewall of the SiGe core 210. The PR mask is removed before or after the EPI growth leaving an epitaxial core 210 and two epitaxial shell portions 215A and 215B, each having a different material and/or dopant concentration.

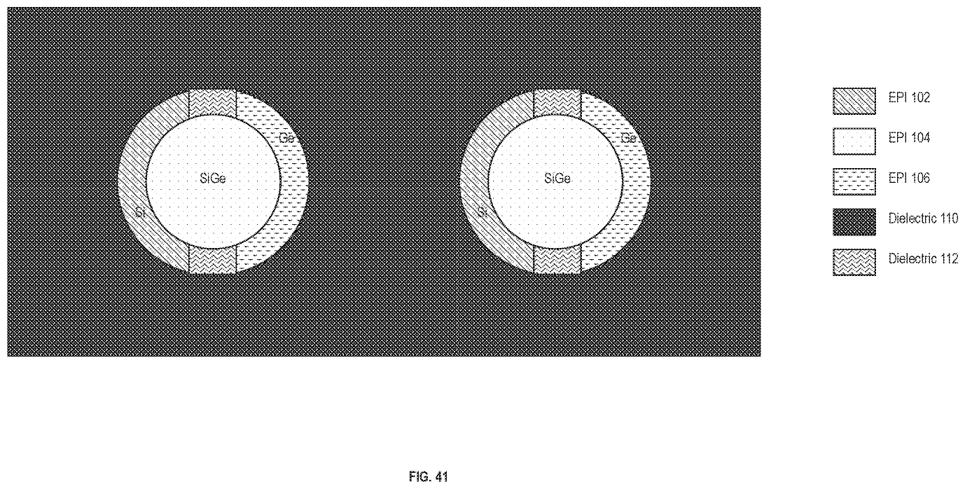

As shown by the resulting structure shown in FIG. 41, a mask/etch/PR STRIP process can be performed in which opening is created where the SiGe EPI 104 shell portion and Ge EPI 106 shell portion meet. One or both layers are etched in the exposed opening to provide isolation between the Si EPI 102 and the Ge EPI 106. EPI 102 and EPI 106 can be etched to dielectric 112 to provide isolation between silicon half-cylinder and Ge half-cylinder. The opening may be left open as an air gap or may be filled with a dielectric material.

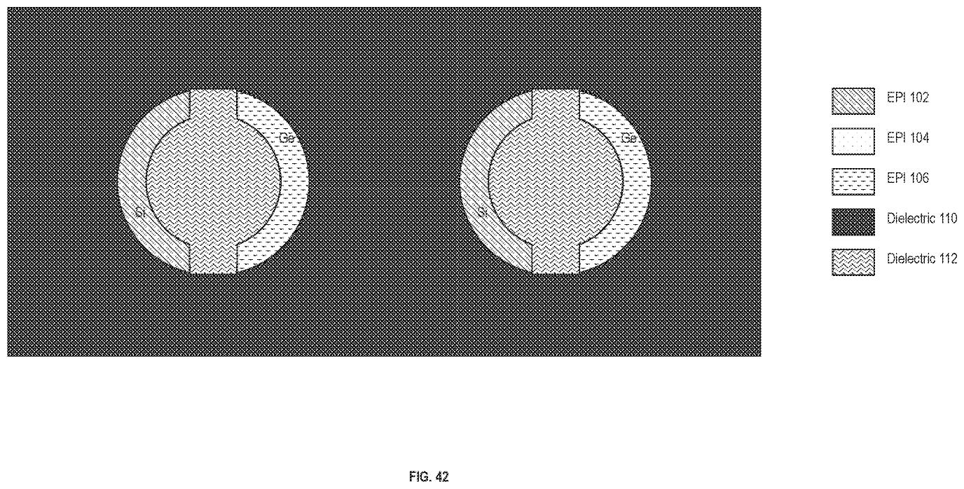

As shown by the resulting structure in FIG. 42, the SiGe core 210 is removed and replaced by additional dielectric 112, further isolating the Si EPI 102 layer from the Ge EPI 106 layer. Thus, through this process, the Si EPI 102 may be isolated for use in further formation of an NMOS device and the Ge EPI 106 may be isolated for use in further formation of a PMOS device as will be further detailed below.

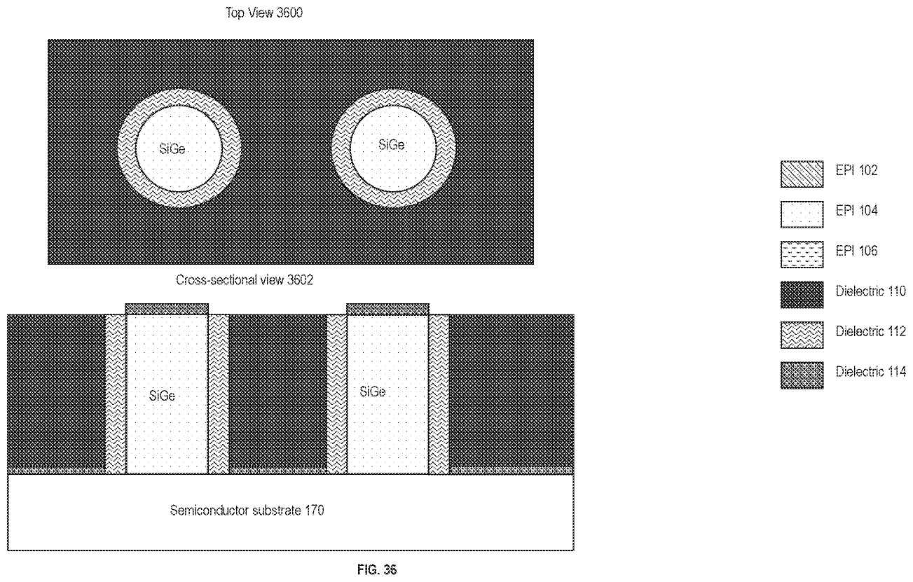

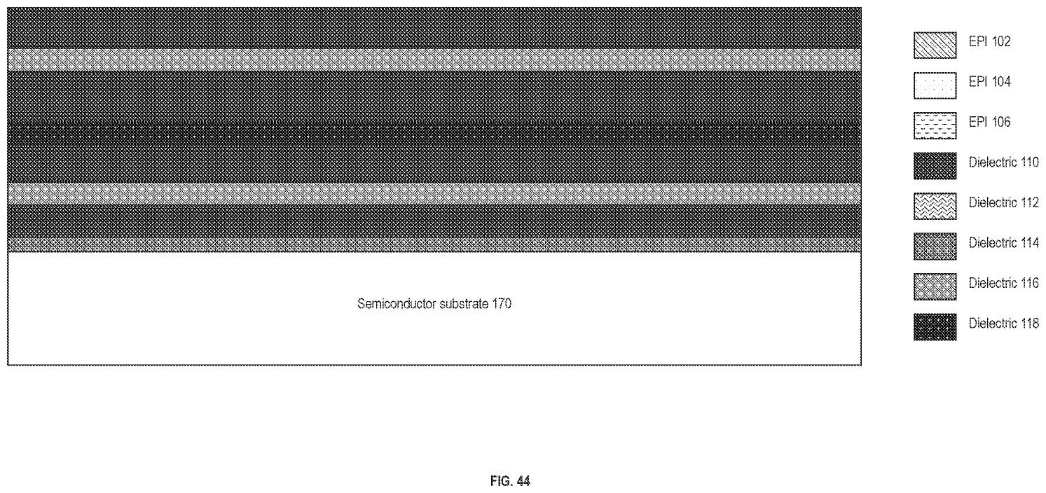

Several alternative variations of the transistor 205 design utilizing different material combinations, in accordance with the steps or techniques discussed in connection with FIGS. 36-42 above, are also presented in FIGS. 32 and 43. Techniques and steps for fabricating the structures shown in FIG. 32 are also presented in FIGS. 33-42, while techniques and steps for fabricating the structures shown in FIG. 43 are also presented in FIGS. 44-59.

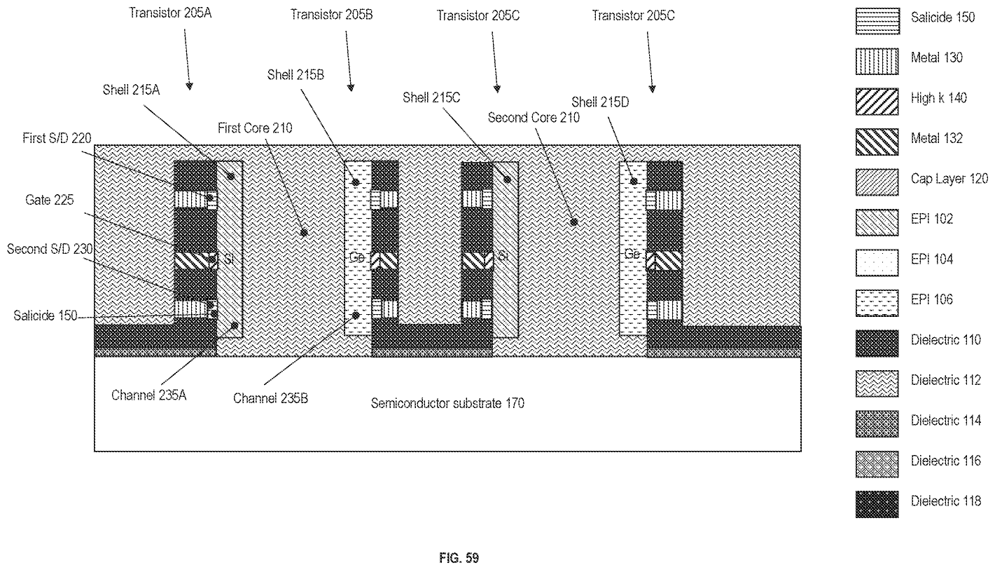

In certain implementations, the EPI shells 215, or partial shells 215, similar to those discussed in connection with FIG. 2, formed on or around a core 210, may form one or more channels 235 of a transistor 205, or a plurality of channels 235 of a plurality of transistors 205. As shown in FIG. 2 and also relevant to FIG. 59, for example, shells/shell portions 215, can provide one or more channel 215 structure for one or more transistors 205. Two S/D contacts 220/230 are coupled to each channel 215 via a self-aligned salicide 150. A gate 225 structure comprising a gate contact (e.g., metal 132) and gate dielectric (e.g., high k 140) control the state of the transistor 205 and are interposed between the two S/D contacts 220/230 with isolation dielectric 110 isolating each contact. The transistor 205 may be formed from a single shell 215 (not shown in FIG. 59, but shown in the example illustrated by FIG. 60-75 or 3-11) or it may be formed from one of multiple shell portions 215A, 215B on each core 210. Each shell portion 215A-N on a core 210 can compose a separate transistor 205, although other devices are contemplated. The channels 230 may be the same material as shown in FIG. 12 or they may be formed of different materials as will be further detailed with reference to the following figures.

The process of formation for multiple transistor structures 205 set about a single core 210 will now be set forth. As shown in FIG. 44, a series of dielectric layers is formed. As will be made more apparent as the process continues, the bottom dielectric, Dielectric 114, is etchable selectively relative to the other dielectric materials. Multiple layers of a different dielectric, Dielectric 110, is formed with a pattern of interspersed dielectrics, Dielectric 116 and 118. Dielectric 116 layers will be sacrificially utilized for forming S/D contacts, while Dielectric 118 will be sacrificially utilized for forming the gate contact and gate dielectric. Each of these materials is selectively etchable relative to the other dielectric layers.

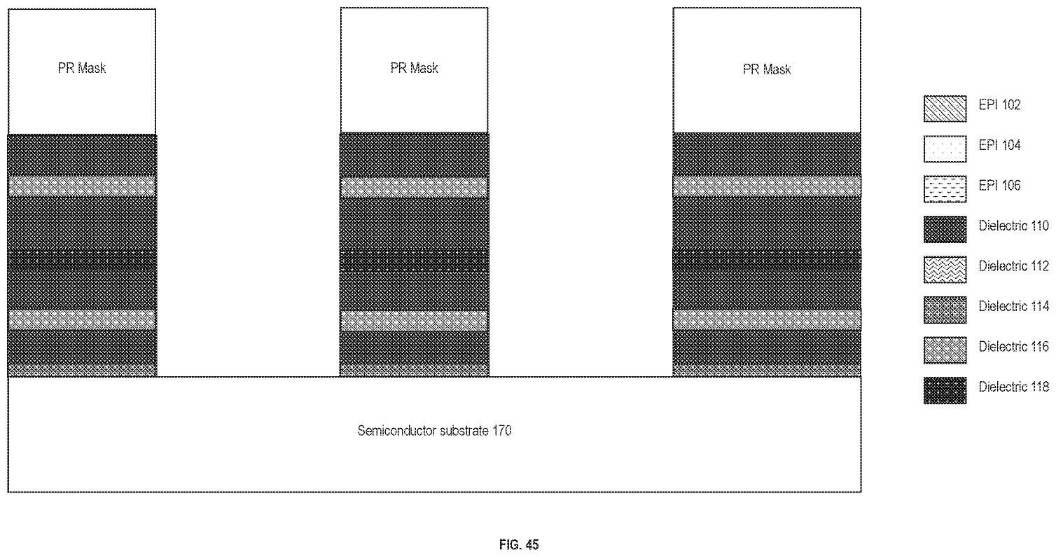

As shown in FIG. 45, a PR mask is formed and patterned to expose the cross-section of the core structure in at least one of the openings of the pattern. The core structure may be any suitable shape, such as circular, oval, polygonal, etc., as the process allows. An etch process is performed to remove layers in the opening down to the underlying semiconductor substrate.

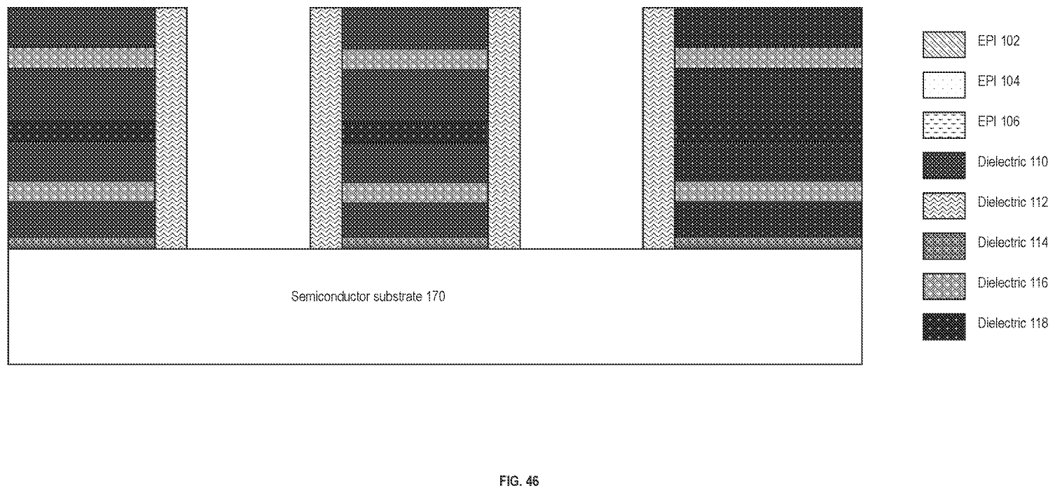

As shown in FIG. 46, dielectric, e.g., dielectric 112, is formed on the sidewalls of the opening. PR mask is removed, followed by dielectric 112 deposition, followed by etching of surplus material.

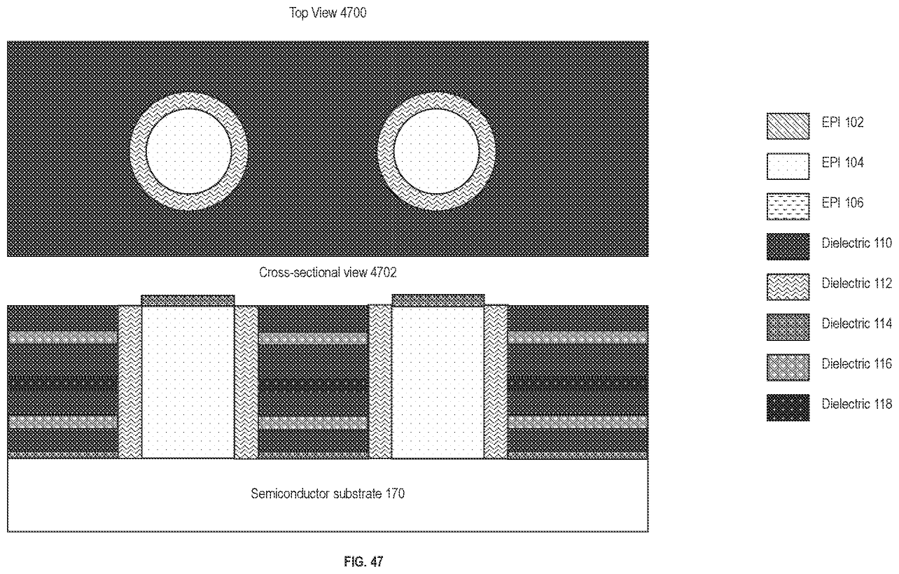

As shown in FIG. 47, a core epitaxial layer (EPI 104 or SiGe) is grown on the exposed semiconductor surface in the opening formed by the dielectric. Once the epitaxial layer is completed, a dielectric cap, e.g., dielectric 114, is formed over the core epitaxial layer to protect it during further processing steps.

As shown in FIG. 48, a photoresist mask (PR mask) is formed to protect a portion of the underlying dielectric 112 layer. The exposed portion of dielectric 112 is removed, e.g., by an atomic layer etch (ALE) process or other suitable removal process. As described above, a portion of dielectric 112 in the bottom of the opening is left unetched to serve as an isolation dielectric. Using this process etching is done to remove a half of the dielectric of the cylinder along the vertical line in order to create a half-cylinder shell 215. While the PR mask is positioned so as to remove about a half of the material, at this stage any mask shape can be used to tailor the amount of dielectric 112 to remove, thereby identifying both the circumferential portion of the shell 215 to form and how many shells to form (as more masks can be used later to create as many as preferred other partial shells 215).

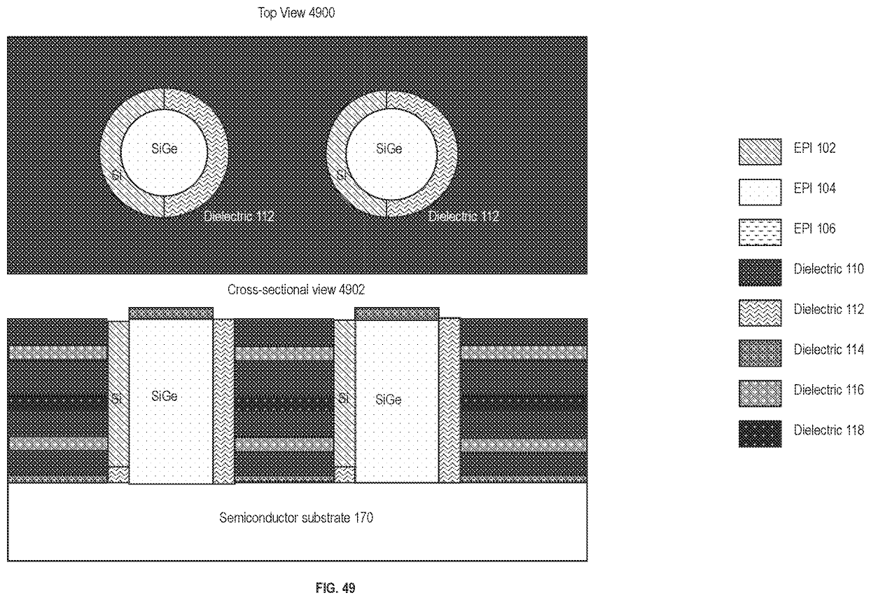

As shown in FIG. 49, including top view 6500 and cross-sectional view 6502, an epi layer (e.g., Si Epi) is formed on the sidewall of the SiGe EPI 104 core 210. The PR mask is removed before or after the epi growth to expose the previously masked portion of dielectric 112. This can be done by PR mask removal, followed by EPI 102 growth, where in the illustrated example, the material grown is N (or N+) doped Silicon. By completing this step, a first shell 215 of the multiple shells on the core 210 is formed, as it surrounds the SiGe EPI 104 based core 210.

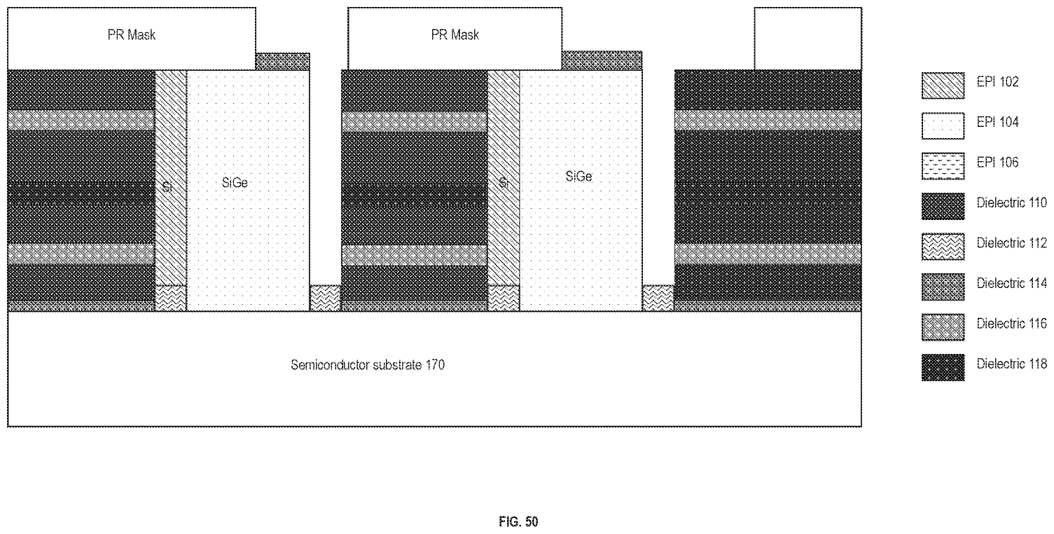

As shown in FIG. 50, a photoresist mask is formed over the freshly grown Si EPI 102 shell 215, to protect the Si EPI 102 layer while exposing another portion of the dielectric 112. As with the prior PR mask used in FIG. 48, this PR mask, by its shape and size, can identify the shape of this shell 215 on the core 210. The smaller the PR mask, the smaller the shell 215 it leaves behind. By repeating this process, as many shells 215 on the core 210 can be formed as preferred by the design. As previously masked dielectric 112 layer is removed, a portion of the dielectric 112 in the bottom of the opening can be left for isolation of the structure from the underlying semiconductor substrate 170. A portion of the dielectric 112 may be covered by the mask to leave dielectric 112 extending along a sidewall of the SiGe core to isolate the Si from the yet-to-be-formed Ge layer.

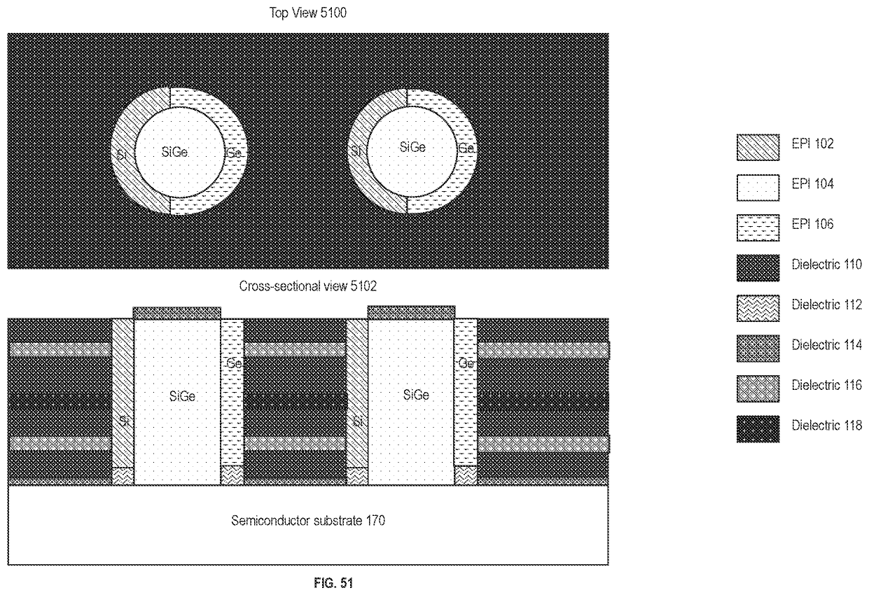

As shown in FIG. 51, including top view 6700 and cross-sectional view 6703, an EPI 106 layer, which in the illustrated embodiment is P (or P+) doped Ge EPI 106, is formed through an epitaxial growth on the SiGe layer. The PR mask is removed before or after the epi growth leaving an epitaxial core 210 with two epitaxial shell 215 portions, each having a different material and/or dopant concentration. As shown in FIG. 51 a first shell 215A can include n type doped Si EPI 102, while the second shell 215B can include p-type doped Ge EPI 106.

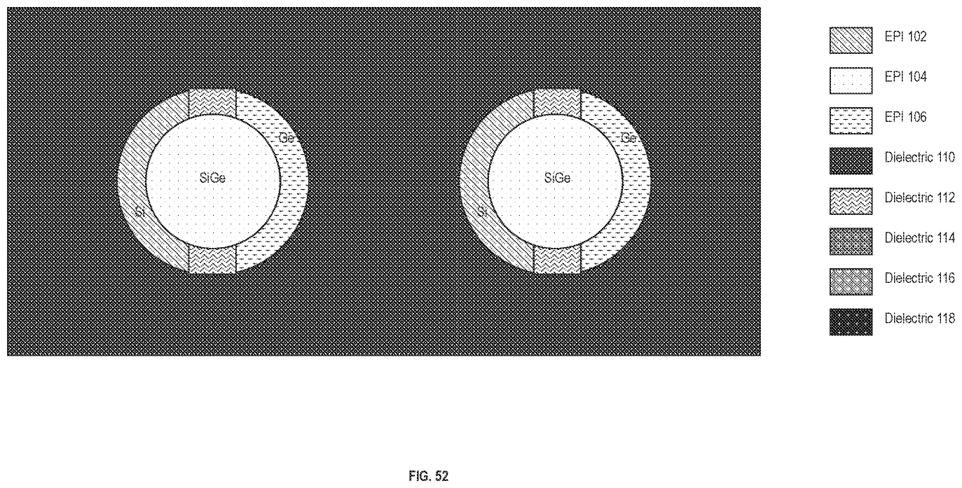

In the event all remaining dielectric 112 was removed adjacent the Si epitaxial layer, a mask/etch/PR STRIP process similar to that described above is used to create an opening where the Si EPI 102 shell 215A portion and Ge EPI 106 shell 215B portion meet. One or both layers are etched in the exposed opening to provide isolation between the Si EPI 102 and the Ge EPI 106 as shown in FIGS. 52-54. Completing this step, electrical isolation between the Si EPI 102 and Ge EPI 106 is formed. As the sections at which Si and Ge shells 215A and 215B meet is etched out (which can be done using a PR mask and directional downward etch), the gap formed where the interface between EPI 102 and EPI 106 used to be can be either left with an air gap or filled with dielectric, such as dielectric 112.

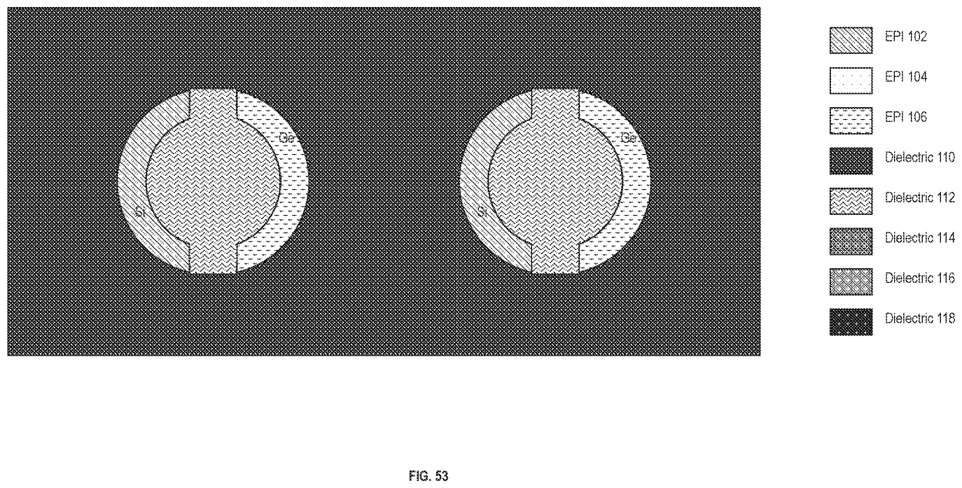

The SiGe core is removed and replaced by additional dielectric 112 (See, FIG. 53) further isolating the Si EPI layer from the Ge EPI layer. Thus, through this process, the Si EPI 102 may be isolated for use in further formation of an NMOS device and the Ge EPI 106 may be isolated for use in further formation of a PMOS device as will be further detailed below.

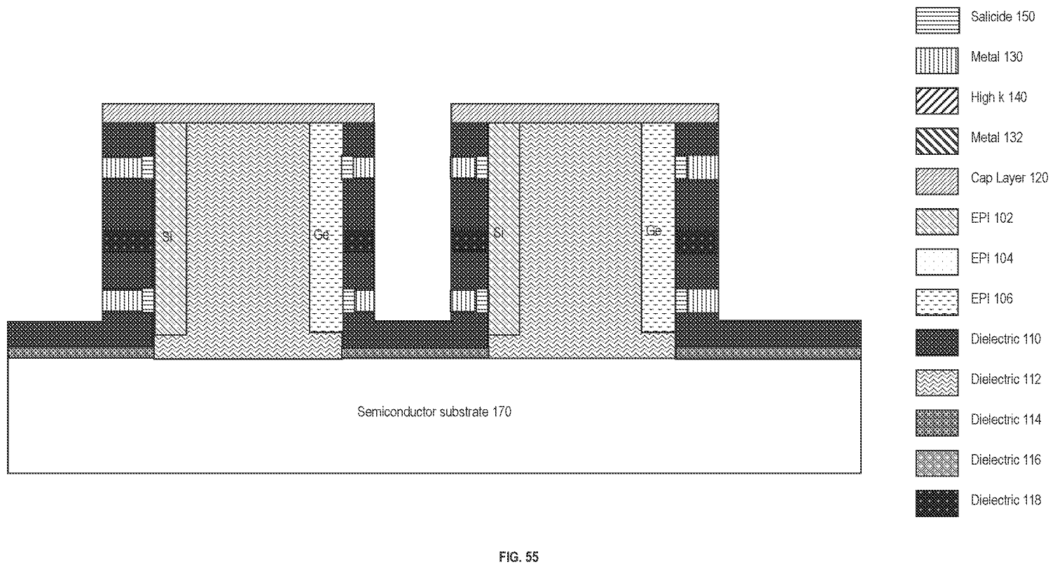

As shown in FIG. 55, deposition, mask, and etch steps are performed to form a Cap Layer 120 on the shell portions as well as a portion of the stacked dielectric layers. An isotropic etch is preformed to remove the dielectric 116 from the locations in which first and second S/D contacts 220 and 230 are to be formed. Once the removal of dielectric 116 is completed, metal 130 can be deposited into the cavity formed by the prior etching of the dielectric 116. As silicide 150 is to be formed (in the illustrated example), metal 130 can be any metal suitable for this purpose, such as Cu, W, Ti, Ni, Ru, Co, etc. Metal 130 is deposited by, e.g., atomic layer deposition (ALD) so that material can enter the horizontally oriented cavity of the S/D contacts 220/230. Once metal 130 is deposited, a heat treatment (e.g., annealing) can be performed to convert a portion of the metal nearest the semiconductor (such as the Si, Ge or any other semiconductor used for the shell 215) to form chemical compounds of improved electrical characteristics, such as silicide or germanicide. The resulting chemical compound in the illustrated example can include salicide 150 formed between Si EPI 102 and metal 130 and germanicide (not shown) formed at the similar interface of Ge EPI 106 and metal 130. Upon completing this fabrication step, both first and second S/D contacts 220/230 for each of the transistors 205 are complete, as well as the salicide 150 and germanicide, or any other similar chemical compound.

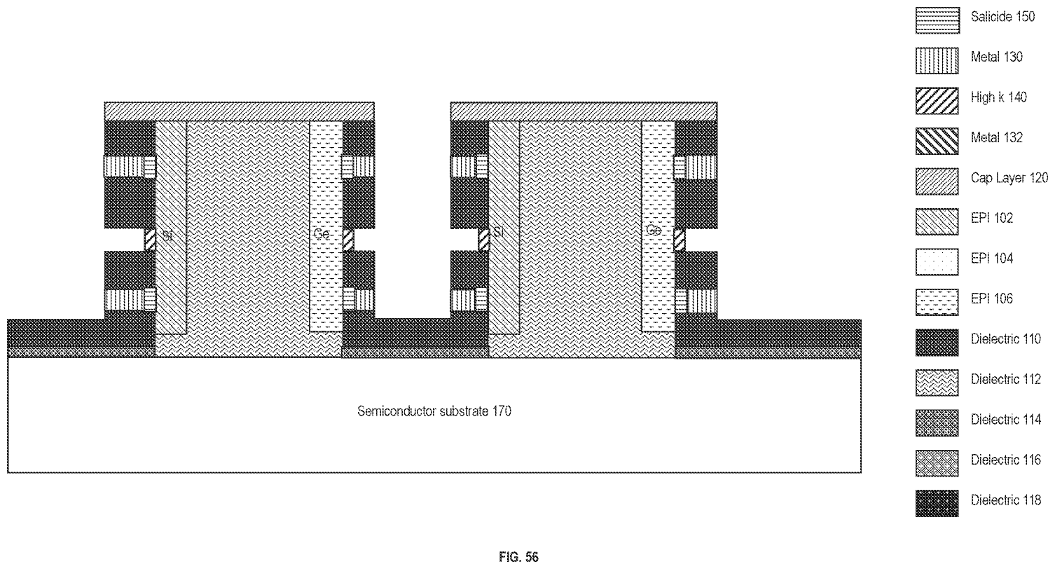

Next, in FIG. 56, dielectric 118 is etched or otherwise removed and a high k 140 dielectric is formed adjacent the Si or Ge channels. By removing the dielectric 118 material that was filling the area in which gate 225 is to be formed, this dielectric 118 material is used as a sacrificial layer in this process. Similarly, other layers of dielectric filling the areas in which S/D contacts 220/230 are to be formed can also serve as sacrificial layers for those contacts. The high-K 140 may be formed by a selective process in which it forms preferentially on the Si or Ge and not on the metal or dielectric layers. In other implementations, the high-k material is conformally formed over the structure and selectively removed by a directional etch using the Cap Layer 120 as a mask.

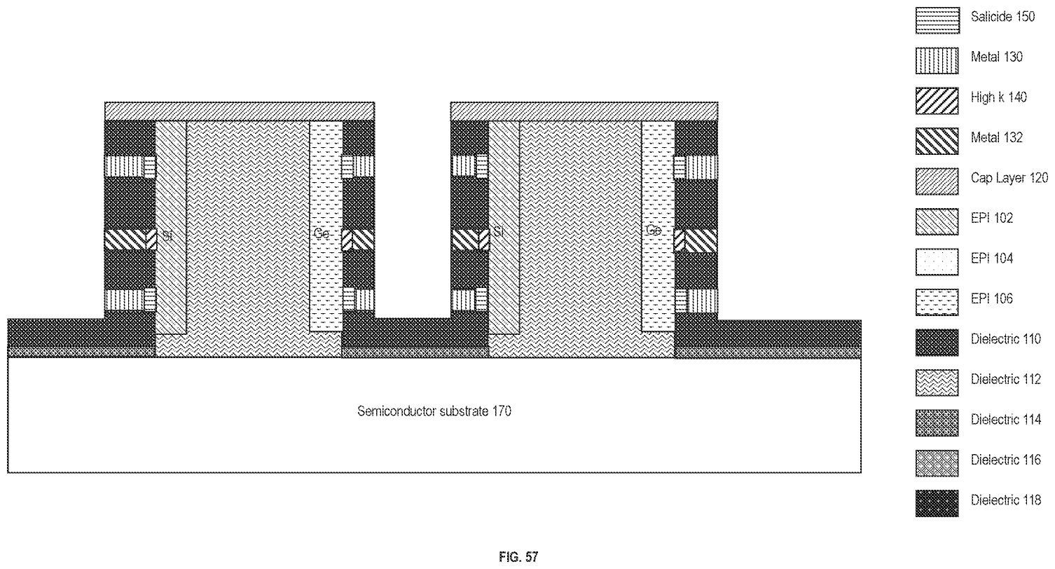

As shown in FIG. 57, a gate metal, (e.g., metal 132) is formed or deposited inside of the remaining opening to form the gate 225 contact and to complete the transistor 205 structures. The resulting gate 225 can include a high-k 140 layer interfaced between the metal 132 line and the semiconductor channel 235 formed by the shells 215A or 215B (or any other shells 215 as may be the case).

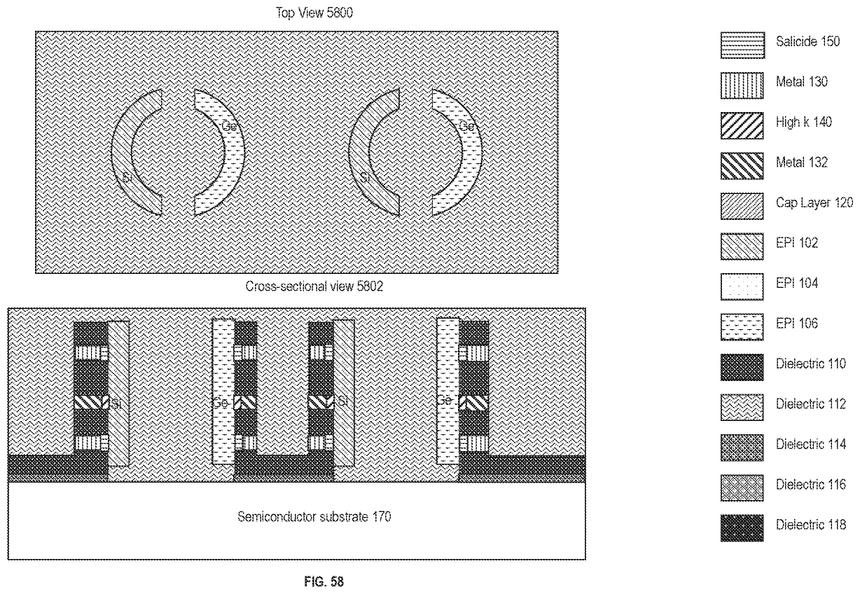

Further dielectric isolation may be formed as shown in FIG. 58, to fill in the empty areas and trenches with dielectric 112. This can provide added electrical and other isolation between different cores 210 and their corresponding shells 215. This can be followed by the formation of interconnections, such as metal lines and contacts to route signals to the S/D contacts 220/230 and to the gate 225 contact, thereby enabling electrical connection to other circuitry (not shown). As one example, vias may be drilled to each contact and filled with dielectric and metal as is known by those skilled in the art. The interconnects may all pass to one side, e.g., to the top of the dielectric or toward (or through) the silicon substrate. The silicon substrate may be subsequently removed and additional transistors, chips or other circuitry may be bonded to one or both sides of the transistor structure.

Referring now to FIG. 59, an embodiment is illustrated in which multiple cores 210 have multiple shells 215 forming their own transistors 205. FIG. 59 shows a first core 210 and a second core 210. The first core 210 has shells 215A and 215B forming their own individual transistors 205A and 205B. Each of the transistors 205A and 205B have their own first and second S/D contacts 220/230 with salicides 150 and the gate 225 contacts. Transistor 205A is formed from a Si EPI 102 shell 215 forming its own channel 235A, while transistor 205B is formed from a Ge EPI 106 shell 215 forming its own channel 235B. However, it is understood that as shell 215B is formed from Ge EPI 106, its chemical compound formed by annealing metal and semiconductor interface can include germanicide layer (not shown) rather than silicide 150.

Similarly, second core 210 will also have the same construction as the first core 210. The shells 215C and 215D can have their own S/D contacts 220/230, gate 235 and salicides 150 (or germanicides in the case of Ge EPI 106 contacts with metal). Shell 215 can form its own channel 235C from Si EPI 102 for transistor 205C, while shell 215D can form its own channel 235D from Ge EPI 106 for transistor 205D. Therefore, in FIG. 59, two cores 210 can provide four transistors formed in vertical shells around cores 210, two being Si-based and two being Ge-based.

The same or similar techniques as those discussed in FIGS. 43-59 above can also be applied to fabricate the structures shown, for example, in FIGS. 60-75, and different materials may be used.

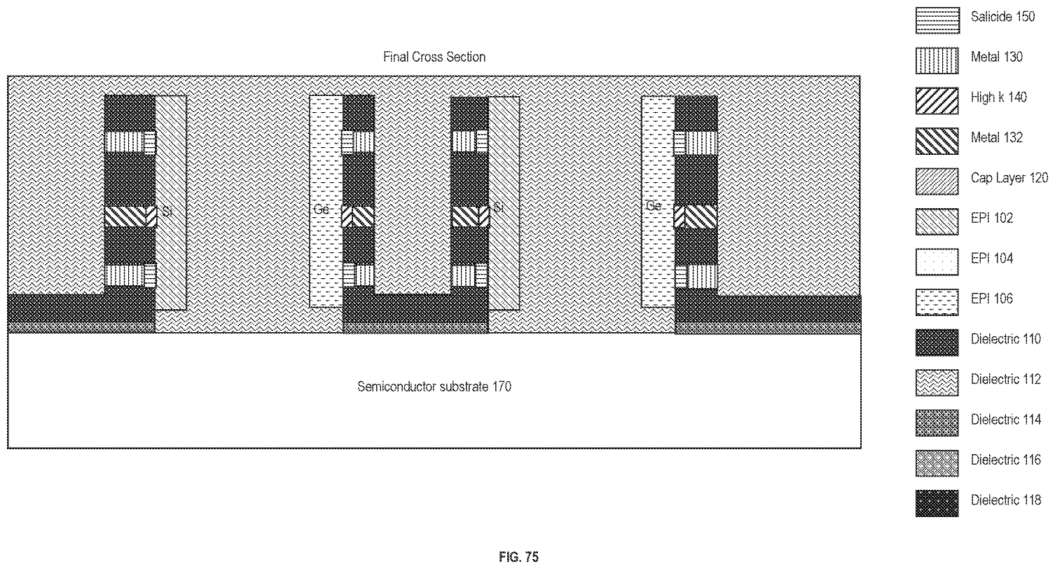

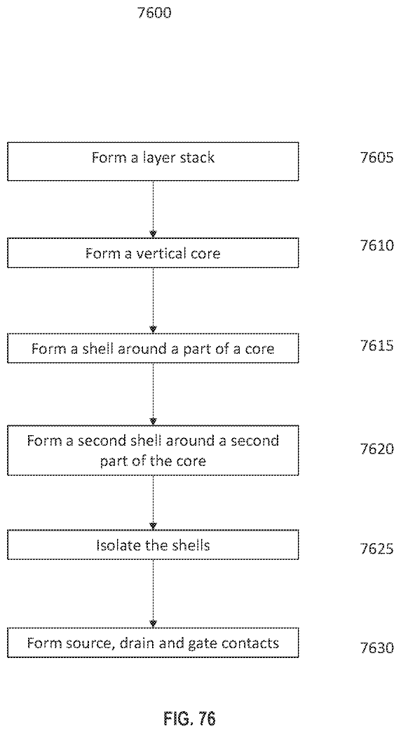

Referring now to FIG. 76, illustrated is a flow diagram of an example method 7600 for fabricating vertical transistor structures 205 using any combination of the fabrication techniques and steps described in FIGS. 1-75. The method 7600 can include steps 7605-7630. At step 7605, the method forms a layer stack. At step 7610, the method forms a vertical core. At step 7615, the method forms a shell around a part of the core. At step 7620, the method forms a second shell around a second part of the core. At step 7625, the method isolates the shells. At step 7630, the method forms source, drain and gate contacts.

At step 7605, method 7600 forms a layer stack. The method can form a stack of layers upon a substrate. The substrate can include any type and form of a substrate, including a semiconductor wafer substrate, a metal substrate, a ceramic substrate, a glass substrate, a plastic substrate or any other type and form of substrate. The stack layer can include a first dielectric layer formed on top of the substrate. The stack layer can include a second dielectric layer formed on top of the first dielectric layer, where the second dielectric layer includes a thickness that is multiple times larger than the thickness of the first dielectric layer. For example, the thickness of the second dielectric layer can be at least 5, 10, 15, 20, 30, 40, 50 or 100 times greater than the thickness of the first layer. The layer stack can be formed, or include characteristics, as illustrated and described in connection with FIG. 4 and its corresponding Figures.

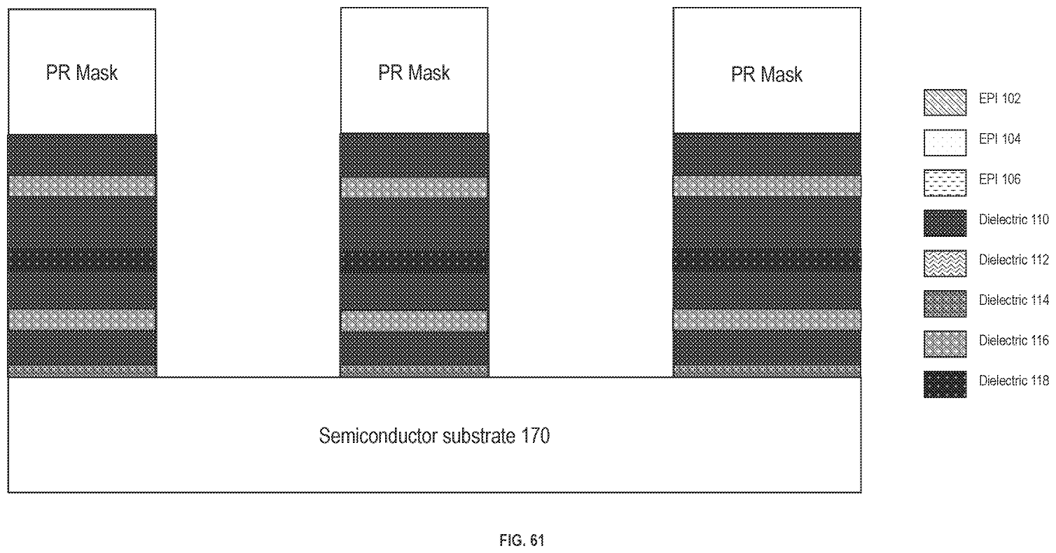

The layer stack can include a first dielectric layer formed on a substrate, on top of which can be a second dielectric layer. On top of the second dielectric layer can be a first sacrificial dielectric layer to be replaced during the process to form source or drain metal contacts. On top of that can be a third dielectric layer, on top of which can be a second dielectric sacrificial layer, on top of which can be another dielectric layer, followed by a third layer of sacrificial dielectric material, followed by another dielectric layer. The layer stack can be formed, or include characteristics, as illustrated and described in connection with FIG. 60 and its corresponding FIGS. 61-75 that describe the usage of those layers during the process.

At step 7610, the method forms a vertical core. The method can form a core comprising a dielectric material extending vertically from a substrate. The core can comprise any epitaxially grown material, such as any dielectric or a semiconductor, including any one of, or any combination of: Si, SiGe and Ge. The method can form a cross-section of the core comprising a portion that is one of: circular, elliptical or polygonal. The core can have a cylindrical form and be shaped as a cylinder, a rod, a bump, a lump, a sphere, a cylinder with a spherical top or any other shape that has one or more sidewalls on which shells can be formed. The core can have a length extending vertically with respect to the plane of the substrate one or more layers of material in the layer stack. The core can have the length smaller, the same as or larger than its width of the cross-section (e.g., diameter). The cross-section of the core can have any shape including: circular, elliptical, triangular, square, rectangular, pentagonal, hexagonal, octagonal, decagonal or any other shape of a polygon. The core can include a post or mandrel supporting one or more shells interface with it or formed on its one or more sidewalls. The method can form the core using, for example, the fabrication steps and techniques shown or described in connection with FIGS. 3-11.

At step 7615, the method forms a shell around a part of the core. The method can form a vertical shell having a cross-section comprising a rounded portion. The vertical shell can include an epitaxially grown semiconductor material that at least partially surrounds the core. The epitaxially grown material can include a doped semiconductor material, such as Si, Ge or SiGe. The vertical shell can have its length oriented vertically with respect to the plane of the substrate or the layer of material deposited on the substrate. The vertical shell can be curved around at least a portion of the core. The vertical shell can form a channel of a transistor device. The method can form the shell by epitaxially growing material in a trench surrounding the outer surface (or surfaces) of a core. The method can form the shell by removing a prior dielectric shell surrounding the sidewall(s) of the core and leaving only a bottom portion of the dielectric shell for isolation. The method can then form the shell on top of the bottom portion of the prior removed dielectric shell.

The method can form the rounded portion of the cross-section of the shell by ALD deposition of a film of material on the core. The method can form the rounded portion by filling in the trench around the core and epitaxially growing the shell. The rounded portion of the cross-section can include an outer surface of the vertical shell in the form of a portion of a circle, ellipse or a shape of any curvature. The cross-section of the shell can include a second rounded portion of the cross-section along an inner surface of the outer shell. The second rounded portion can have a shape of a portion of a circle, ellipse or a shape of any curvature. The second rounded portion can be defined by the shape of core to which it is attached or with which it interfaces. The cross-section of the vertical shell can include a portion that is one of: circular, elliptical or polygonal.

The vertical shell can extend across a first portion of the outer surface of the core. For example, the vertical shell can form a cylindrical ring around a cylindrical core, fully surrounding the core from all sides around an axis that is perpendicular to the plane of the substrate. The vertical shell can form a semi-circle around the core, covering about a half of the outer sidewall(s) of the cylindrical core along the core's length. Similarly, the vertical shell can form a shell around a third of a circle around the outer sidewall(s) of the core, or a quarter of a circle around the core. The vertical shell can include a portion that covers the top of the core. The method can form the vertical shell using, for example, the fabrication steps and techniques shown or described in connection with FIGS. 3-11.

At step 7620, the method forms a second shell around a second part of the core. The method can form a second vertical shell having a rounded cross-section. The second vertical shell can include an epitaxially grown second semiconductor material that at least partially surrounds the dielectric core and forms a second channel of a second transistor. The second vertical shell extends across a second portion of the outer surface of the core. The method can form a second vertical shell on the core in accordance with fabrication steps and methodologies illustrated or discussed, for example, in connection with FIG. 47-59 or 63-74.

The second vertical shell can cover a part of the core that the first vertical shell does not cover. For example, a first vertical shell, such as the one in step 7615, can form a first portion of an outer surface of a core, while the second vertical shell can cover a second portion of the outer surface of the core. Likewise, a third vertical shell can cover a third portion of the outer surface of the core and a fourth vertical shell can cover a fourth portion of the outer surface of the core. Each shell on the outer surface of the core can cover a portion of a sidewall of the core, or one or more sidewalls of the core.

The material of a first shell can be different from the material of a second shell. The for example, the semiconductor material of the vertical shell formed at step 7615 can be different from the second semiconductor material of the second shell. For example, the vertical shell can be formed with one of the Si, Ge or SiGe material, while the second vertical shell can be formed from a different one of the Si, Ge or SiGe material. The semiconductor material of the vertical shell can include a first material dopant type and the second semiconductor of the second vertical shell on the core can include a second material dopant type that is different from than the first material dopant type. A first shell can include the same material as the second shell, but different dopant type.

The shells formed from epitaxially grown doped semiconductor can form channels of one or more transistors. In some embodiments, each shell forms a channel for an individual transistor. In some embodiments, a core can comprise multiple shells, each one of which forms its own channel for its own individual transistor. In some embodiments, a core can comprise multiple shells, each one of which forms a channel for a multi-channel transistor on the core. In some embodiments, all shells on a core form their own channels for a single multi-channel transistor of that core.

At step 7625, the method isolates the shells. The method can form a dielectric vertical shell having the cross-section comprising the rounded portion and at least partially surrounding the core. The method can remove a top portion of the dielectric vertical shell. The method can form the vertical shell on top of a bottom portion of the dielectric vertical shell that is left behind after removal of the top of the dielectric vertical shell. The bottom portion of the dielectric vertical shell can isolate the vertical shell formed by epitaxial material on top of the bottom portion from the substrate beneath. The method can isolate the shell from the substrate using, for example, the fabrication steps and techniques shown or described in connection with FIGS. 6-9.

The semiconductor material can be electrically insulated from the second semiconductor material by one or more layers of dielectric. For example, a region in which a vertical shell and a second vertical shell interface or touch on the outer surface of the core can be etched out and filled with a dielectric material for electrical isolation. The core can be etched out and filled with dielectric material to provide isolation between two or more shells. The final core of the structure can include a dielectric core on which one or more semiconductor shells are formed. The method can isolate the shells from each other using, for example, the fabrication steps and techniques shown or described in connection with FIGS. 52-54.

At step 7630, the method forms source, drain and gate contacts. The method can form a first source/drain contact on an outer surface of the shell. The method can form a second source/drain contact on the outer surface of the shell and vertically aligned with the first source/drain contact. The method can form a gate contact on an outer surface of the shell, the gate contact located between, and vertically aligned with, the first source/drain contact and the second source/drain contact. The method can form a gate contact on an outer surface of the shell, the gate contact located between, and vertically aligned with, the first source/drain contact and the second source/drain contact. The method can form a first source/drain contact extending along an outer surface of the cross-section of the vertical shell and a second source/drain contact extending along an outer surface of the second cross-section of the vertical shell.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements and features described only in connection with one implementation are not intended to be excluded from a similar role in other implementations or implementations.

The phraseology and terminology used herein is for the purpose of description and should not be regarded as limiting. The use of “including” “comprising” “having” “containing” “involving” “characterized by” “characterized in that” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act or element may include implementations where the act or element is based at least in part on any information, act, or element.

Any implementation disclosed herein may be combined with any other implementation, and references to “an implementation,” “some implementations,” “an alternate implementation,” “various implementation,” “one implementation” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The preceding description of the disclosed embodiments is provided to enable any person skilled in the art to make or use the embodiments described herein and variations thereof. Various modifications to these embodiments will be readily apparent to those skilled in the art, and the principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

While various aspects and embodiments have been disclosed, other aspects and embodiments are contemplated. The various aspects and embodiments disclosed are for purposes of illustration and are not intended to be limiting, with the true scope and spirit being indicated by the following claims.

What is claimed is:

1. A device comprising:
a core comprising a dielectric material extending vertically from a substrate; and
a vertical shell having a cross-section comprising a rounded portion, the vertical shell comprising an epitaxially grown semiconductor material that at least partially surrounds the core and forms a channel of a transistor.

2. The device of claim 1, further comprising:
a bottom portion of a dielectric vertical shell isolating the substrate from the vertical shell that is formed thereon, wherein the dielectric vertical shell has a cross-section comprising the rounded portion and at least partially surrounding the core.

3. The device of claim 1, further comprising:
a first source/drain contact on an outer surface of the shell; and
a second source/drain contact on the outer surface of the shell and vertically aligned with the first source/drain contact.

4. The device of claim 1, further comprising a gate contact on an outer surface of the shell, the gate contact located between, and vertically aligned with, the first source/drain contact and the second source/drain contact.

5. The device of claim 1, further comprising:
a first source/drain contact extending along an outer surface of the cross-section of the vertical shell and a second source/drain contact extending along an outer surface of the second cross-section of the vertical shell.

6. The device of claim 1, wherein the rounded portion of the cross-section comprises an outer surface of the vertical shell and wherein the cross-section further comprises a second rounded portion of the cross-section along an inner surface of the outer shell.

7. The device of claim 1, comprising:
a cross-section of the core comprising a portion that is one of: circular, elliptical or polygonal,
wherein the cross-section of the vertical shell comprises a portion that is one of: circular, elliptical or polygonal.

8. The device of claim 1, wherein the vertical shell extends across a first portion of the outer surface of the core, comprising:
a second vertical shell having a rounded cross-section and comprising an epitaxially grown second semiconductor material that at least partially surrounds the dielectric core and forms a second channel of a second transistor, wherein the second vertical shell extends across a second portion of the outer surface of the core.

9. The device of claim 8, wherein the semiconductor material is different from the second semiconductor material and wherein the semiconductor material is electrically insulated from the second semiconductor material by one or more layers of dielectric.

10. The device of claim 8, wherein the semiconductor material comprises a first material dopant type and the second semiconductor comprises a second material dopant type that is different from than the first material dopant type.

11. A method comprising:
forming a core comprising a dielectric material extending vertically from a substrate and having a rounded shape; and
forming a vertical shell having a surface that contacts the core and includes a rounded portion defined by the rounded shape of the core, the vertical shell comprising an epitaxially grown semiconductor material that at least partially surrounds the core and forms a channel of a transistor.

12. The method of claim 11, further comprising:
forming a dielectric vertical shell that contacts and at least partially surrounds the core and includes a rounded portion defined by the rounded shape of the core;
removing a top portion of the dielectric vertical shell; and
forming the vertical shell on top of a bottom portion of the dielectric vertical shell, wherein the bottom portion isolates the vertical shell from the substrate.

13. The method of claim 11, further comprising:
forming a first source/drain contact on an outer surface of the shell; and
forming a second source/drain contact on the outer surface of the shell and vertically aligned with the first source/drain contact.

14. The method of claim 11, further comprising:
forming a gate contact on an outer surface of the shell, the gate contact located between, and vertically aligned with, the first source/drain contact and the second source/drain contact.

15. The method of claim 11, further comprising:
forming a first source/drain contact extending along a surface of the vertical shell opposite the core and a second source/drain contact extending along an outer surface of the vertical shell.

16. The method of claim 11, further comprising replacing a preliminary core with the core comprising the dielectric material.

17. The method of claim 11, further comprising:
forming a cross-section of the core comprising a portion that is one of: circular, elliptical or polygonal,
wherein a surface of the vertical shell is defined by the cross-section.

18. The method of claim 17, wherein the vertical shell extends across a first portion of the outer surface of the core, the method further comprising:
forming a second vertical shell with a surface defined by the cross-section and comprising an epitaxially grown second semiconductor material that at least partially surrounds the core and forms a second channel of a second transistor, wherein the second vertical shell extends across a second portion of the outer surface of the core.

19. The method of claim 18, wherein the semiconductor material is different from the second semiconductor material and wherein the semiconductor material is electrically insulated from the second semiconductor material by one or more layers of dielectric.

20. The method of claim 18, wherein the semiconductor material comprises a first material dopant type and the second semiconductor comprises a second material dopant type that is different from than the first material dopant type.
